(19) United States
(12) Patent Application Publication
(10) Pub. No.: US 2021/0384237 A1
(43) Pub. Date: Dec. 9, 2021

(54) SOLID-STATE IMAGING ELEMENT AND IMAGING DEVICE

(71) Applicant: SONY SEMICONDUCTOR SOLUTIONS CORPORATION, Kanagawa (JP)

(72) Inventor: Shinya YAMAKAWA, Kanagawa (JP)

(73) Assignee: SONY SEMICONDUCTOR SOLUTIONS CORPORATION, Kanagawa (JP)

(21) Appl. No.: 17/288,088

(22) PCT Filed: Oct. 10, 2019
(86) PCT No.: PCT/JP2019/039986

§ 371 Date: Apr. 23, 2021

(30) Foreign Application Priority Data
Oct. 30, 2018 (JP) 2018-203704

(51) Int. Cl. H01L 27/146; H04N 5/378; H04N 5/374

(52) U.S. Cl. CPC H01L 27/14603; H04N 5/378; H01L 27/14683; H01L 27/14625; H01L 27/14643; H04N 5/3741

(57) ABSTRACT

A solid-state imaging element including: a first substrate including a photoelectric conversion section and a transfer transistor electrically coupled to the photoelectric conversion section; a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and a drive circuit that allows a signal electric charge generated in the photoelectric conversion section to be outputted through the transfer transistor and the output transistor.

### TECHNICAL FIELD

The present technology relates to a solid-state imaging element including a photoelectric conversion section, and an imaging device.

### BACKGROUND ART

In recent years, image sensors are used not only in applications of photographing images but also applications such as monitoring and automated driving of automobiles. In such image sensors, for example, solid-state imaging elements such as CCD (Charge Coupled Device) and CMOS (Complementary Metal Oxide Semiconductor), etc., are used.

Solid-state imaging elements include, for example, a photoelectric conversion section and an output transistor. The photoelectric conversion section is provided for each pixel. The output transistor outputs signal electric charges generated in the photoelectric conversion section to a drive circuit (for example, refer to PTL 1).

### CITATION LIST

### Patent Literature

PTL 1: Japanese Unexamined Patent Application Publication No. 2012-54876

### SUMMARY OF THE INVENTION

In such a solid-state imaging element, it is desired to suppress noise.

It is therefore desirable to provide a solid-state imaging element and an imaging device including the solid-state imaging element that make it possible to suppress noise.

A solid-state imaging element (1) according to an embodiment of the present disclosure includes: a first substrate including a photoelectric conversion section and a transfer transistor electrically coupled to the photoelectric conversion section; a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and a drive circuit that allows a signal electric charge generated in the photoelectric conversion section to be outputted through the transfer transistor and the output transistor.

An imaging device (1) according to an embodiment of the present disclosure includes the solid-state imaging element (1) according to the forgoing embodiment of the present disclosure.

A solid-state imaging element (2) according to an embodiment of the present disclosure includes: a photoelectric conversion section; a transfer transistor electrically coupled to the photoelectric conversion section; an output transistor electrically coupled to the transfer transistor and including a channel region of a first electrical conductivity type, a gate electrode including a plurality of faces that covers the channel region, and source-drain regions of the first electrical conductivity type adjacent to the channel region; and a drive circuit that allows a signal electric charge generated in the photoelectric conversion section to be outputted through the transfer transistor and the output transistor.

An imaging device (2) according to an embodiment of the present disclosure includes the solid-state imaging element (2) according to the forgoing embodiment of the present disclosure.

In the solid-state imaging elements (1) and (2) and the imaging devices (1) and (2) according to the embodiments of the present disclosure, the output transistor includes the channel region of the same electrical conductivity type (first conductivity type) as the electrical conductivity type of the source-drain regions. Thus, a current path of the channel region is formed away from an interface on side on which the gate electrode is disposed. This makes it less likely that carriers flowing in the channel region are trapped by the interface on the side on which the gate electrode is disposed.

It is to be noted that effects described below are not necessarily limited, and any effect described in the present disclosure may be provided.

### BRIEF DESCRIPTION OF DRAWING

FIG. 1 is a block diagram illustrating an example of a functional configuration of an imaging element according to a first embodiment of the present disclosure.

FIG. 2 is a diagram illustrating an example of a circuit configuration of a pixel illustrated in FIG. 1.

FIG. 3 is a schematic plan view illustrating an example of a configuration of the pixel illustrated in FIG. 1.

FIG. 4A is a schematic view illustrating a cross-sectional configuration along an A-A′ line illustrated in FIG. 3.

FIG. 4B is a schematic view illustrating a cross-section along a B-B′ line illustrated in FIG. 3.

FIG. 5 is a schematic cross-sectional view illustrating another example of a configuration of a gate electrode illustrated in FIG. 4B.

FIG. 6A is a schematic cross-sectional view corresponding to FIG. 4A of an amplification transistor according to a comparative example.

FIG. 6B is a schematic cross-sectional view corresponding to FIG. 4B of the amplification transistor according to the comparative example.

FIG. 7 is a schematic cross-sectional view illustrating a current path flowing in an amplification transistor illustrated in FIG. 4B.

FIG. 8 is a schematic cross-sectional view illustrating a configuration of an imaging element according to a modification example 1.

FIG. 9 is a schematic cross-sectional view illustrating a configuration of an imaging element according to a modification example 2.

FIG. 10 is a diagram illustrating an example of a circuit configuration of a pixel of an imaging element according to a modification example 3.

FIG. 11 is a schematic view illustrating an example of a plan configuration of the imaging element illustrated in FIG. 10.

FIG. 12 is a schematic diagram illustrating, in outline, a configuration of a main portion of an imaging element according to a second embodiment of the present disclosure.

FIG. 13 is a diagram illustrating an example of a pixel and a readout circuit in FIG. 12.

FIG. 14 is a diagram illustrating an example of the pixel and the readout circuit in FIG. 12.

FIG. 15 is a diagram illustrating an example of the pixel and the readout circuit in FIG. 12.

FIG. 16 is a diagram illustrating an example of the pixel and the readout circuit in FIG. 12.

FIG. 17 is a diagram illustrating an example of a coupling mode between a plurality of readout circuits and a plurality of vertical signal lines.

FIG. 18 is a view illustrating an example of a cross-sectional configuration in a vertical direction of the imaging element in FIG. 12.

FIG. 19 is a schematic plan view illustrating a configuration of a main portion of an imaging element according to a modification example 4.

FIG. 20A is a schematic view illustrating a cross-sectional configuration along an A-A′ line illustrated in FIG. 19.

FIG. 20B is a schematic view illustrating a cross-sectional configuration along a B-B′ line illustrated in FIG. 19.

FIG. 21A is a schematic cross-sectional view illustrating a process of a method of manufacturing the imaging element illustrated in FIG. 20A, etc.

FIG. 21B is a schematic cross-sectional view illustrating a process following FIG. 21A.

FIG. 21C is a schematic cross-sectional view illustrating a process following FIG. 21B.

FIG. 22A is a schematic cross-sectional view illustrating another example of a process following FIG. 21C.

FIG. 22B is a schematic cross-sectional view illustrating a process following FIG. 22A.

FIG. 22C is a schematic cross-sectional view illustrating a process following FIG. 22B.

FIG. 22D is a schematic cross-sectional view illustrating a process following FIG. 22C.

FIG. 22E is a schematic cross-sectional view illustrating a process following FIG. 22D.

FIG. 22F is a schematic cross-sectional view illustrating a process following FIG. 22E.

FIG. 22G is a schematic cross-sectional view illustrating a process following FIG. 22F.

FIG. 22H is a schematic cross-sectional view illustrating a process following FIG. 22G.

FIG. 23 is a schematic cross-sectional view illustrating a configuration of a main portion of an imaging element according to a modification example 5.

FIG. 24 is a diagram illustrating an example of a cross-sectional configuration in a horizontal direction of the imaging element in FIG. 23.

FIG. 25 is a diagram illustrating an example of the cross-sectional configuration in the horizontal direction of the imaging element in FIG. 23.

FIG. 26 is a diagram illustrating an example of a wiring layout in a horizontal plane of the imaging element in FIG. 23.

FIG. 27 is a diagram illustrating an example of the wiring layout in the horizontal plane of the imaging element in FIG. 23.

FIG. 28 is a diagram illustrating an example of the wiring layout in the horizontal plane of the imaging element in FIG. 23.

FIG. 29 is a diagram illustrating an example of the wiring layout in the horizontal plane of the imaging element in FIG. 23.

FIG. 30 is a view illustrating an example of a cross-sectional configuration in the vertical direction of an imaging element according to a modification example 6.

FIG. 31 is a diagram illustrating an example of a cross-sectional configuration in the horizontal direction of an imaging element according to a modification example 7.

FIG. 32 is a diagram illustrating another example of a cross-sectional configuration in the horizontal direction of the imaging element illustrated in FIG. 23.

FIG. 33 is a diagram illustrating an example of a cross-sectional configuration in the horizontal direction of an imaging element according to a modification example 8.

FIG. 34 is a diagram illustrating an example of a cross-sectional configuration in the horizontal direction of an imaging element according to a modification example 9.

FIG. 35 is a diagram illustrating an example of a cross-sectional configuration in the horizontal direction of an imaging element according to a modification example 10.

FIG. 36 is a diagram illustrating another example (1) of the cross-sectional configuration in the horizontal direction of the imaging element illustrated in FIG. 35.

FIG. 37 is a diagram illustrating another example (2) of the cross-sectional configuration in the horizontal direction of the imaging element illustrated in FIG. 35.

FIG. 38 is a diagram illustrating an example of a circuit configuration of the imaging element according to the second embodiment and the modification examples thereof described above.

FIG. 39 is a diagram illustrating an example in which the imaging element in FIG. 38 includes three substrates that are stacked.

FIG. 40 is a diagram illustrating an example in which a logic circuit is separated to be formed in a substrate on which a pixel P is provided, and a substrate on which the readout circuit is provided.

FIG. 41 is a diagram illustrating an example in which the logic circuit is formed in a third substrate.

FIG. 42 is a diagram illustrating an example of a schematic configuration of an imaging device including the imaging element according to the embodiments and the modification examples thereof described above.

FIG. 43 is a diagram illustrating an example of an imaging procedure in the imaging device in FIG. 42.

FIG. 44 is a block diagram depicting an example of a schematic configuration of an in-vivo information acquisition system.

FIG. 45 is a view depicting an example of a schematic configuration of an endoscopic surgery system.

FIG. 46 is a block diagram depicting an example of a functional configuration of a camera head and a camera control unit (CCU).

FIG. 47 is a block diagram depicting an example of schematic configuration of a vehicle control system.

FIG. 48 is a diagram of assistance in explaining an example of installation positions of an outside-vehicle information detecting section and an imaging section.

### MODES FOR CARRYING OUT THE INVENTION

In the following, some embodiments of the present technology are described in detail with reference to the drawings. It is to be noted that description is given in the following order.

1. First Embodiment (an example of a solid-state imaging element provided with an amplification transistor including a channel region of the same electrical conductivity type as source-drain regions)
2. Modification Example 1 (an example in which the amplification transistor has a Fin FET (Field Effect Transistor) structure)
3. Modification Example 2 (an example in which the amplification transistor has a GAA (Gate All Around) structure)
4. Modification Example 3 (an example in which the amplification transistor is shared by a plurality of pixels)
5. Second Embodiment (an example of a solid-state imaging element having a stacked structure of a first substrate, a second substrate, and a third substrate)
6. Modification Example 4 (an example in which a reset transistor, an amplification transistor, and a selector transistor have the Fin FET structure)
7. Modification Example 5 (an example with an FTI (Full Trench Isolation) structure)
8. Modification Example 6 (an example in which Cu—Cu bonding is used at an outer edge of a panel)
9. Modification Example 7 (an example in which an offset is provided between a pixel and a readout circuit)
10. Modification Example 8 (an example in which a silicon substrate on which a readout circuit is provided has an island shape)
11. Modification Example 9 (an example in which the silicon substrate on which the readout circuit is provided has the island shape)
12. Modification Example 10 (an example in which an FD is shared by four pixels P)
13. Modification Example 11 (an example in which a signal processing circuit includes a common column ADC circuit)
14. Modification Example 12 (an example in which an imaging element includes three substrate that are stacked)
15. Modification Example 13 (an example in which a logic circuit is provided on a first substrate and a second substrate)
16. Modification Example 14 (an example in which a logic circuit is provided on a third substrate)
17. Application Example (an example of an electronic apparatus)

### 18. Practical Application Examples

### First Embodiment

### (Overall Configuration of Imaging Element 10)

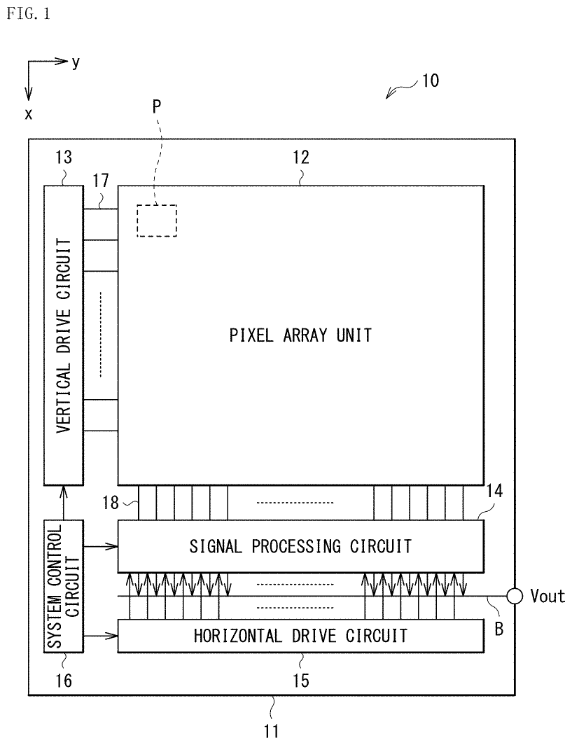

FIG. 1 is a block diagram illustrating an example of a functional configuration of a solid-state imaging element (imaging element 10) according to a first embodiment of the present disclosure. The imaging element 10 is, for example, an amplification type solid-state imaging element such as a CMOS image sensor. The imaging element 10 may be other amplification type solid-state imaging elements, or a solid-state imaging element of charge transfer type such as CCD.

The imaging element 10 includes a semiconductor substrate 11 on which a pixel array unit 12 and a peripheral circuit unit are provided. The pixel array unit 12 is provided in, for example, a center portion of the semiconductor substrate 11, while the peripheral circuit unit is provided outside the pixel array unit 12. The peripheral circuit unit includes, for example, a vertical drive circuit 13, a signal processing circuit 14, a horizontal drive circuit 15, and a system control circuit 16.

In the pixel array unit 12, unit pixels (pixels P) are two-dimensionally disposed in a matrix. The unit pixels each include a photoelectric conversion section that generates signal electric charges of an amount of electric charges corresponding to an amount of entering light, and accumulates the signal electric charges inside. In other words, the plurality of the pixels P is disposed along an X direction (first direction) and a Y direction (second direction) in FIG. 1. The “unit pixel” as used herein is an imaging pixel for acquisition of an imaging signal. Specific circuit configurations of the pixel P (imaging pixel) are described later.

In the pixel array unit 12, for the pixel arrangement in the matrix, pixel drive lines 17 are wired along a row direction (direction of arrangement of pixels in a pixel row) for respective pixel rows, and vertical signal lines 18 are wired along a column direction (direction of arrangement of pixels in a pixel column) for respective pixel columns. The pixel drive lines 17 transfer a drive signal for pixel driving. The drive signal is outputted in units of rows from the vertical drive circuit 13. In FIG. 1, the pixel drive line 17 is illustrated as a single wiring, but not limited to the single wiring. One end of the pixel drive line 17 is coupled to an output terminal corresponding to each row of the vertical drive circuit 13.

The vertical drive circuit 13 includes, for example, a shift register and an address decoder, and drives each pixels of the pixel array unit 12, for example, in units of rows. Here, illustration of specific configurations of the vertical drive circuit 13 is omitted, but in general, the vertical drive circuit 13 has a configuration including two scanning systems, i.e., a readout scanning system and a discharge scanning system.

The readout scanning system performs sequential selective scanning of the unit pixels of the pixel array unit 12, in units of rows, to read out a signal from the unit pixel. The signal to be read out from the unit pixel is an analog signal. The discharge scanning system performs discharge scanning of a readout row to be subjected to readout scanning by the readout scanning system, in advance of the readout scanning by the time of a shutter speed.

By the discharge scanning by the discharge scanning system, unnecessary electric charges are discharged from the photoelectric conversion section of the unit pixel in the readout row, causing the photoelectric conversion section to be reset. Thus, by the discharge (reset) of the unnecessary electric charges by the discharge scanning system, a so-called electronic shutter operation is carried out. Here, the electronic shutter operation refers to an operation of dumping the signal electric charges in the photoelectric conversion section to newly start exposure (start accumulation of signal electric charges).

The signal to be read out by a readout operation by the readout scanning system corresponds to an amount of entering light on and after a preceding readout operation or the electronic shutter operation. Moreover, a period from readout timing by the preceding readout operation or discharge timing by the electronic shutter operation to readout timing by the current readout operation serves as an accumulation period (exposure period) of signal electric charges in the unit pixel.

The signal to be outputted from each of the unit pixels of the pixel row subjected to the selective scanning by the vertical drive circuit 13 is supplied to the signal processing circuit 14 through each of the vertical signal lines 18. The signal processing circuit 14 performs, for each pixel column of the pixel array unit 12, predetermined signal processing on the signal to be outputted through the vertical signal line 18 from each pixel of a selected row, and temporarily holds the pixel signal after the signal processing.

Specifically, the signal processing circuit 14 receives the signal of the unit pixel, and performs, on the signal, signal processing such as noise elimination by CDS (Correlated Double Sampling), signal amplification, and AD (Analog-Digital) conversion, etc. By the noise elimination process, reset noise and pixel-specific fixed pattern noise such as threshold variation of an amplification transistor is removed. Note that the signal processing exemplified here is merely an example, and the signal processing is not limited to these. Here, the signal processing circuit 14 corresponds to a specific example of the drive circuit of the present disclosure.

The horizontal drive circuit 15 includes, for example, a shift register and an address decoder, and performs sequential selective scanning of a unit circuit corresponding to the pixel column of the signal processing circuit 14. By the selective scanning by the horizontal drive circuit 15, the pixel signal subjected to the signal processing by each unit circuit of the signal processing circuit 14 is outputted to a horizontal bus B in order, and transmitted to outside the semiconductor substrate 11 through the horizontal bus B.

The system control circuit 16 receives, for example, a clock given from outside the semiconductor substrate 11, and data that gives a command of an operation mode. Moreover, the system control circuit 16 outputs data such as internal information of the imaging element 10. Furthermore, the system control circuit 16 includes a timing generator that generates various timing signals. On the basis of the various timing signals generated in the timing generator, the system control circuit 16 carries out a drive control of the peripheral circuit unit such as the vertical drive circuit 13, the signal processing circuit 14, and the horizontal drive circuit 15.

### (Circuit Configuration of Pixel P)

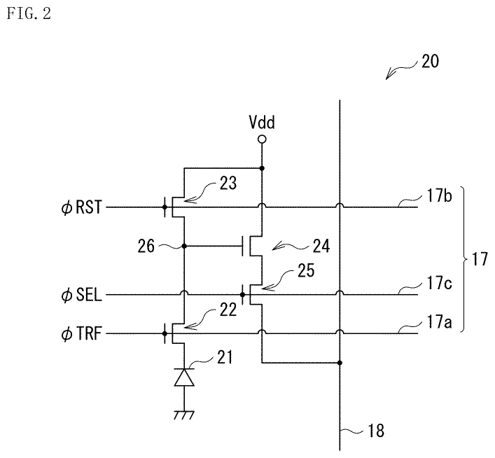

FIG. 2 is a circuit diagram illustrating an example of a readout circuit 20 that outputs the pixel signal based on the electric charges outputted from each pixel P.

Each pixel P includes, for example, a photodiode 21, as the photoelectric conversion section. To the photodiode 21 provided for each pixel P, for example, a transfer transistor 22, a reset transistor 23, an amplification transistor 24, and a selection transistor 25 are coupled. Here, a specific example of an output transistor of the present disclosure is the amplification transistor 24.

Moreover, with respect to the pixel P, as the pixel drive line 17, three drive wirings, e.g., a transfer line 17a, a reset line 17b, and a selection line 17c, are provided in common for each pixel P of the same pixel row. One end of each of the transfer line 17a, the reset line 17b, and the selection line 17c is coupled, in units of pixel rows, to the output terminal corresponding to each pixel row of the vertical drive circuit 13, to transfer a transfer pulse φTRF, a reset pulse φRST, and a selection pulse φSEL as the drive signal that drives the pixel P.

The photodiode 21 includes an anode electrode coupled to a negative-side power supply (e.g., ground), and performs photoelectric conversion of received light (entering light) into signal electric charges of an amount of electric charges corresponding to an amount of the light, to accumulate the signal electric charges. The photodiode 21 includes a cathode electrode electrically coupled to a gate electrode of the amplification transistor 24 through the transfer transistor 22. A node electrically coupled to the gate electrode of the amplification transistor 24 is referred to as an FD (floating diffusion) section 26 (electric charge accumulation section).

The transfer transistor 22 is coupled between the cathode electrode of the photodiode 21 and the FD section 26. To a gate electrode of the transfer transistor 22, the transfer pulse φTRF in which a high level (e.g., Vdd level) is active (hereinafter, referred to as High active) is given through the transfer line 17a. Thus, the transfer transistor 22 is brought to a conductive state, causing the signal electric charges photoelectrically converted by the photodiode 21 to be transferred to the FD section 26.

The reset transistor 23 includes a drain electrode coupled to a pixel power supply Vdd, and a source electrode coupled to the FD section 26. To a gate electrode of the reset transistor 23, the reset pulse φRST of High active is given through the reset line 17b. Thus, the reset transistor 23 is brought to a conductive state, and the FD section 26 is reset by discharging the electric charges of the FD section 26 to the pixel power supply Vdd.

The amplification transistor 24 includes a gate electrode coupled to the FD section 26, a drain electrode coupled to the pixel power supply Vdd. Thus, the amplification transistor 24 outputs, as a reset signal (reset level) Vrst, a potential of the FD section 26 after being reset by the reset transistor 23. Furthermore, the amplification transistor 24 outputs, as an optical accumulation signal (signal level) Vsig, the potential of the FD section 26 after the signal electric charges are transferred by the transfer transistor 22.

The selection transistor 25 includes, for example, a drain electrode coupled to the source electrode of the amplification transistor 24, and a source electrode coupled to the vertical signal line 18. To a gate electrode of the selection transistor 25, the selection pulse φSEL of High active is given through the selection line 17c. Thus, the selection transistor 25 is brought to a conductive state, bringing the unit pixel P to a selected state, and causing the signal supplied from the amplification transistor 24 to be outputted to the vertical signal line 18.

The vertical signal line 18 is coupled to a transistor (not illustrated) of a constant current source biased at a constant voltage. Accordingly, the amplification transistor 24, the selection transistor 25, and the vertical signal line 18 constitute a so-called source follower circuit.

In the example of FIG. 2, a circuit configuration is given in which the selection transistor 25 is coupled between the source electrode of the amplification transistor 24 and the vertical signal line 18. However, a circuit configuration may be also adopted in which the selection transistor 25 is coupled between the pixel power supply Vdd and the drain electrode of the amplification transistor 24.

A circuit configuration of each pixel P is not limited to that of the pixel configuration including the four transistors described above. For example, other pixel configurations may be also possible that includes, for example, three transistors one of which serves as both the amplification transistor 24 and the selection transistor 25. There is no limitation on configurations of the pixel circuit.

### (Specific Configuration of Pixel P)

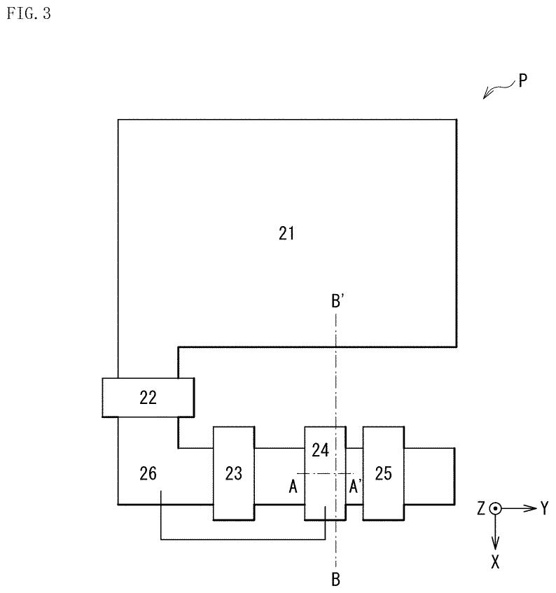

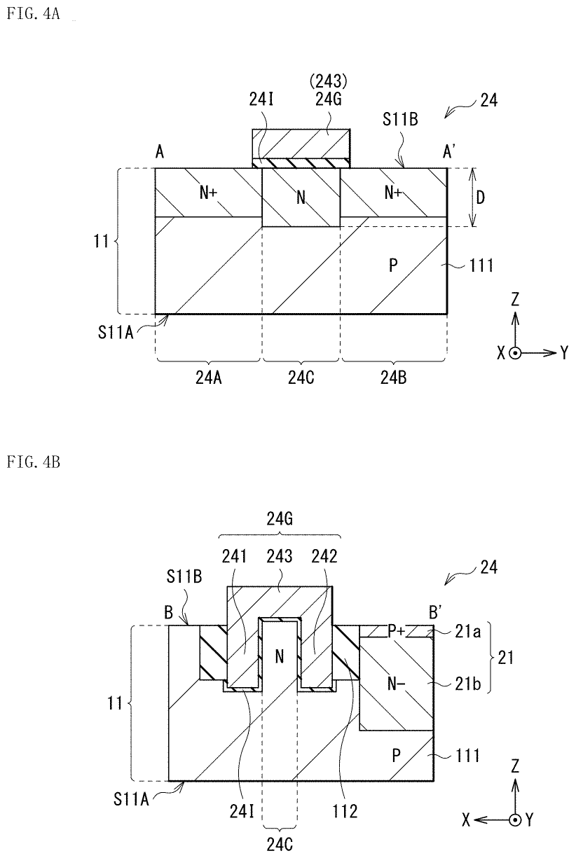

In the following, a specific configuration of the pixel P is described with reference to FIGS. 3, 4A, and 4B. FIG. 3 schematically illustrates a plan configuration of the pixel P. FIGS. 4A and 4B schematically illustrates, respectively, a cross-sectional configuration along an A-A′ line illustrated in FIG. 3, and a cross-sectional configuration along a B-B′ line illustrated in FIG. 3.

The imaging element 10 is, for example, an imaging element of a backside illumination type. Over a wide region of each pixel P, for example, the photodiode 21 having a substantially rectangular planar shape is provided. In the vicinity of an end of each pixel P, for example, the reset transistor 23, the amplification transistor 24, and the selection transistor 25 are arranged side by side in this order. Between the reset transistor 23 and the photodiode 21, the FD section 26 and the transfer transistor 22 are provided (FIG. 3). The amplification transistor 24 is provided on one-surface (surface SUB to be described later) side of the semiconductor substrate 11, and includes a gate electrode 24G, a gate insulating film 241, a channel region 24C, and a pair of source-drain regions 24A and 24B.

The semiconductor-substrate 11 includes a surface S11A on light-entering side, and the surface S11B opposed to the surface S11A. The semiconductor substrate 11 includes, for example, silicon (Si). In the semiconductor substrate 11, for each pixel P, the photodiode 21 is provided. The photodiode 21 is, for example, a photodiode having a pn junction, and includes a p-type impurity region 21a and an n-type impurity region 21b formed in a p-type well region 111. For example, the p-type impurity region 21a and the n-type impurity region 21b are provided in this order along a thickness direction from side of the semiconductor substrate 11 on which the surface S11B is disposed. For example, a size of the p-type impurity region 21a in a depth direction (Z direction in FIG. 4B) is about 30 nm to 200 nm. A size of the n-type impurity region 21b in the depth direction is about 1 μm to 5 μm. For example, an impurity concentration of the p-type impurity region 21a is about 1×10¹⁸ cm⁻³ to 1×10¹⁹ cm⁻³. An impurity concentration of the n-type impurity region 21b is about 1×10¹⁵ cm⁻³×1×10¹⁸ cm⁻³. An impurity concentration of the p-type well region 111 is, for example, about 1×10¹⁶ cm⁻³ to 1×10¹⁸ cm⁻³.

In the vicinity of the surface S11B inside the semiconductor substrate 11, the channel region 24C and the pair of the source-drain regions 24A and 24B of the amplification transistor 24 are provided. The pair of the source-drain regions 24A and 24B is, for example, impurity diffusion regions of n-type (first electrical conductivity type) formed in the p-type well region 111, and is provided adjacent to the channel region 24C. Along a channel length direction (Y direction in FIG. 4A) of the amplification transistor 24, the source-drain region 24A, the channel region 24C, and the source-drain region 24B are provided in this order. An impurity concentration of the source-drain regions 24A and 24B is, for example, about 1×10¹⁹ cm⁻³×1×10²¹ cm⁻³. In the present embodiment, the channel region 24C of the amplification transistor 24 includes the impurity diffusion region of n-type, that is, the same electrical conductivity type as the source-drain regions 24A and 24B. In other words, the amplification transistor 24 has a junction-less structure. Although details are described later, this makes it less likely that carriers flowing in the channel region 24C are captured (trapped) at an interface with the gate insulating film 241. Hence, it is possible to suppress occurrence of noise in the amplification transistor 24.

The channel region 24C disposed between the pair of the source-drain regions 24A and 24B is an n-type impurity diffusion region formed in the p-type well region 111. An impurity concentration of this channel region 24C is about 5×10¹⁷ cm⁻³×1×10¹⁹ cm⁻³. The channel region 24C is surrounded by the gate electrode 24G. A size of the channel region 24C in the channel length direction is, for example, about 200 nm to 3000 nm. A size of the channel region 24C in a channel width direction (X direction in FIG. 4B) is, for example, about 20 nm to 200 nm. A size (size D) of the channel region 24C in a depth direction is, for example, larger than a size of the pair of the source-drain regions 24A and 24B in the depth direction, and is about 50 nm to 500 nm.

The gate electrode 24G surrounding the channel region 24C includes a pair of opposite side faces 241 and 242, and an upper face 243 that joins the pair of the side faces 241 and 242. The pair of the side faces 241 and 242, and the upper face 243 are each opposed to the channel region 24C. In other words, the pair of the side faces 241 and 242, and the upper face 243 form a recess shape surrounding the channel region 24C.

The pair of the side faces 241 and 242 is a plane substantially perpendicular to the surface S11B of the semiconductor substrate 11 (YZ plane in FIG. 4B), and is opposed to the channel width direction. The channel region 24C is provided between the pair of the side faces 241 and 242. A portion or all of the pair of the side faces 241 and 242 are buried in the semiconductor substrate 11. Within the pair of the side faces 241 and 242, a size in the depth direction of the portion buried in the semiconductor substrate 11 is, for example, about 100 nm to 500 nm.

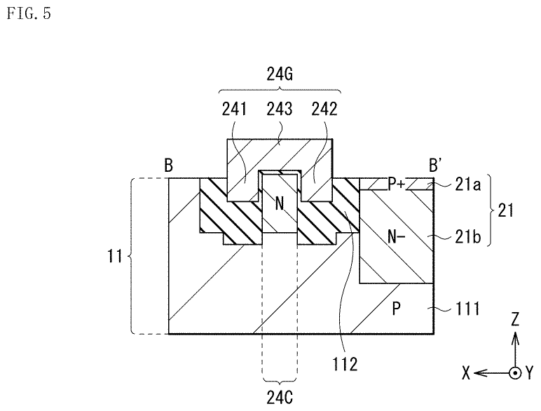

FIG. 5 illustrates another example of the pair of the side faces 241 and 242. A portion of the channel region 24C may be exposed from the pair of the side faces 241 and 242. It is preferable that half or more of the size of the channel region 24C in the depth direction be covered with the pair of the side faces 241 and 242.

The upper face 243 is a plane substantially parallel to the surface S11B of the semiconductor substrate 11 (XY plane in FIG. 3B), and is provided outside the semiconductor substrate 11. That is, the upper face 243 is provided to be opposed to the semiconductor substrate 11. The upper face 243 is in contact with one end of each of the pair of the side faces 241 and 242.

The gate electrode 24G including the pair of the side faces 241 and 242, and the upper face 243 includes, for example, polysilicon (Poly-Si) of p-type (second electrical conductivity type), etc. The gate electrode 24G may include a metal such as tungsten (W), titanium (Ti), titanium nitride (TiN), hafnium (Hf), hafnium silicide (HfSi), ruthenium (Ru), iridium (Ir), and cobalt (Co).

Between each of the pair of the side faces 241 and 242, and the upper face 243, and the channel region 24C, the gate insulating film 241 is provided. The gate insulating film 241 includes an insulating film such as, for example, silicon oxide (SiO). A thickness of the gate insulating film 241 is, for example, about 3 nm to 15 nm.

Around the side faces 241 and 242 buried in the semiconductor substrate 11, element isolation regions (STIs: Shallow Trench Isolation) 112 are provided. The element isolation regions 112 include, for example, an insulating material such as silicon oxide, etc. Inside the semiconductor substrate 11, between the side face 242 and the photodiode 21, the element isolation region 112 is provided.

### (Operation of Imaging Element 10)

In the imaging element 10, light (for example, light of a wavelength in a visible region) enters the photodiode 21 from the surface S11A of the semiconductor substrate 11, and thereupon, pairs of holes and electrons are generated in the photodiode 21 (photoelectric conversion is carried out). The transfer transistor 22 is turned on, and thereupon, the signal electric charges accumulated in the photodiode 21 are transferred to the FD section 26. In the FD section 26, the signal electric charges are converted into a voltage signal, and the voltage signal is outputted to the vertical signal line 18 through the amplification transistor 24 and the selection transistor 25.

### (Workings and Effects of Imaging Element 10)

In the imaging element 10 of the present embodiment, the amplification transistor 24 is a so-called junction-less transistor, and includes the channel region 24C of the same electrical conductivity type as the electrical conductivity type (n-type) of the source-drain regions 24A and 24B. This causes a current path in the channel region 24C to be formed away from the interface with the gate insulating film 241, making it less likely that carriers flowing in the channel region 24C to be trapped at the interface with the gate insulating film 241. In the following, the workings and effects are described using a comparative example.

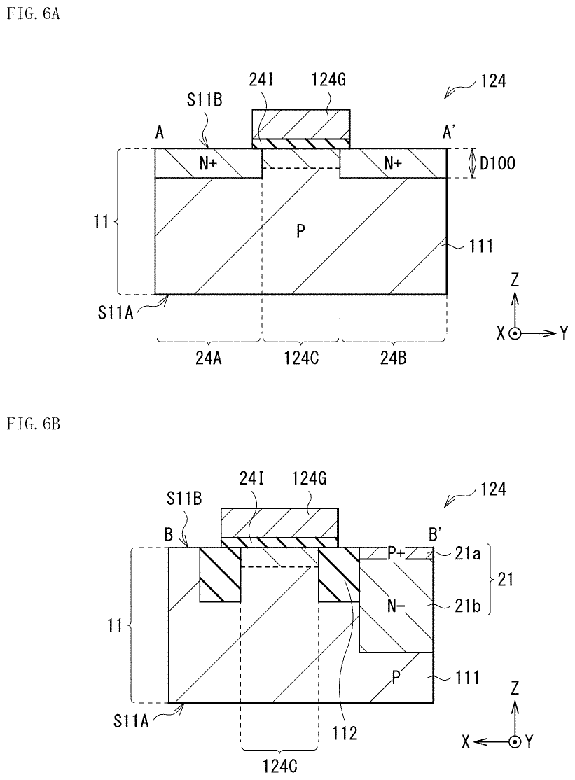

FIGS. 6A and 6B illustrate a schematic cross-sectional configuration of an amplification transistor (amplification transistor 124) according to the comparative example. FIG. 6A corresponds to a cross-sectional configuration along the A-A′ line in FIG. 3, and FIG. 6B corresponds to a cross-sectional configuration along the B-B′ line in FIG. 3. A gate electrode (gate electrode 124G) of the amplification transistor 124 includes solely a single plane provided outside the semiconductor substrate 11. The gate electrode 124G is not buried in the semiconductor substrate 11. A channel region 124C opposed to the gate electrode 124G includes, for example, an impurity diffusion region of an opposite electrical conductivity type (p-type) to the electrical conductivity type (n-type) of the pair of the source-drain regions 24A and 24B. The channel region 124C may be low-concentration n-type, but it is difficult to increase a size (size D100) of the channel region 124C in the depth direction (Z direction in FIG. 6A). One reason for this is because turning on and off of the amplification transistor 124 is controlled by the gate electrode 124G provided solely outside the semiconductor substrate 11. The size D100 in the depth direction of the channel region 124C is, for example, about 50 nm, and is smaller than the size in the depth direction of the source-drain regions 24A and 24B.

In such an amplification transistor 124, a current path in the channel region 124C is formed in the vicinity of an interface with the gate insulating film 241. Accordingly, the presence of a trap level in the gate insulating film 241 causes carriers flowing in the channel region 124C to be captured by the trap level or released from the trap level. This results in occurrence of fluctuation of the current flowing in the channel region 124C. This fluctuation of the current contributes to generation of noise.

A possible method of suppressing the noise may be to increase occupied area of the amplification transistor. However, in this method, occupied area of a photodiode provided in the same semiconductor substrate as the amplification transistor is reduced. This has influences on, for example, sensitivity and an amount of saturation of accumulation of signal electric charges.

In contrast, in the imaging element 10, the channel region 24C includes the n-type impurity diffusion region of a high impurity concentration. Thus, the vicinity of the interface between the channel region 24C and the gate insulating film 241 becomes a depletion layer, causing the current path in the channel region 24C to be formed at a position away from the gate insulating film 241.

FIG. 7 schematically illustrates a current (current C) flowing in the amplification transistor 24 in an on state. Thus, in the amplification transistor 24, most of the current C flows through a central portion in the depth direction of the channel region 24C. In addition, the pair of the side faces 241 and 242 of the gate electrode 24G are buried in the semiconductor substrate 11. This makes it possible to increase the size D (FIG. 4A) of the channel region 24C in the depth direction.

Accordingly, even in a case with the presence of a trap level in the gate insulating film 241, carriers flowing in the channel region 24C of the amplification transistor 24 are hardly trapped by this trap level. Thus, the generation of the noise due to the fluctuation of the current flowing in the channel region 24C is suppressed.

Furthermore, the noise is suppressed, without increasing the occupied area of the amplification transistor 24. This makes it possible to maintain the occupied area of the photodiode 21. Accordingly, the influences on, for example, the sensitivity and the amount of saturation of the accumulation of the signal electric charges are also suppressed.

As described above, in the imaging element 10 of the present embodiment, the amplification transistor 24 includes the channel region 24C of the same electrical conductivity type (n-type) as the electrical conductivity type of the source-drain regions 24A and 24B. This makes it possible to reduce the noise due to the carriers trapped at the interface on side of the channel region 24C on which the gate electrode 24G is disposed. Hence, it is possible to suppress the noise.

Moreover, in the imaging element 10, the pair of the side faces 241 and 242 of the gate electrode 24G are buried in the semiconductor substrate 11. This makes it easier to increase the size D in the depth direction of the channel region 24C. Hence, it is possible to suppress the generation of the noise more effectively.

In the imaging element 10, it is possible to suppress the noise, and to achieve a high SN ratio. Accordingly, for example, even in nighttime photographing, it is possible to obtain a clear image.

In the following, modification examples of the forgoing first embodiment and other embodiments are described. However, in the following description, the same constituent parts as those of the forgoing first embodiment are denoted by the same reference characters, and the description thereof is omitted as appropriate.

### Modification Example 1

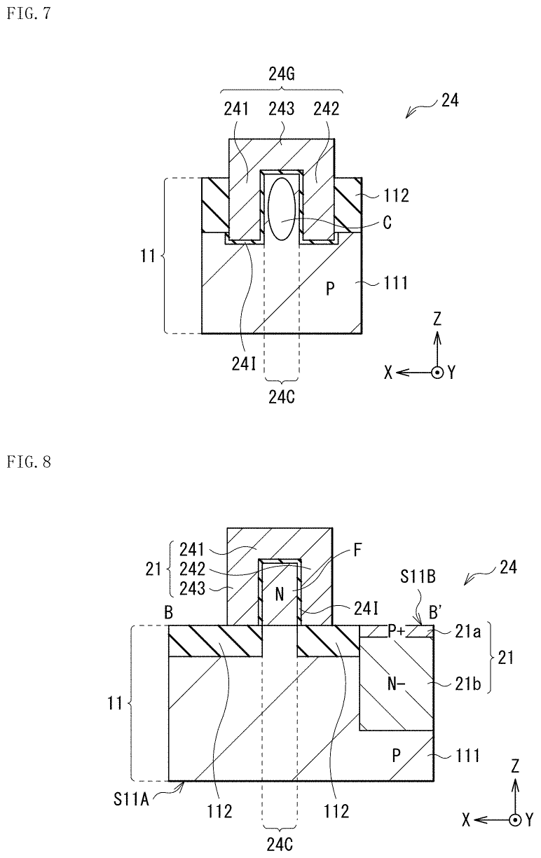

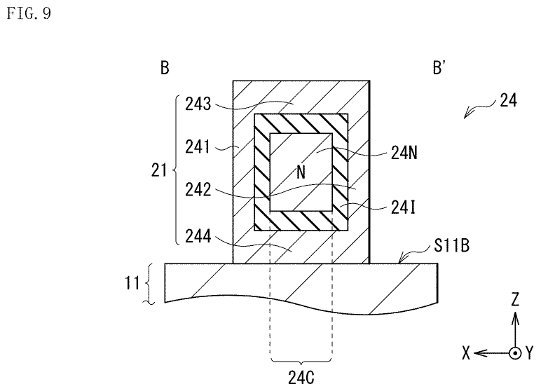

FIG. 8 illustrates a schematic cross-sectional configuration of a main portion of the imaging element 10 (FIG. 1) according to a modification example 1 of the forgoing first embodiment. FIG. 8 corresponds to the cross-sectional configuration along the B-B′ line in FIG. 3. The imaging element 10 includes the amplification transistor 24 having a Fin FET structure. Otherwise, the imaging element 10 according to the modification example 1 has a similar configuration to the imaging element 10 of the forgoing first embodiment, and has similar workings and effects as well.

The amplification transistor 24 having the Fin FET structure includes a fin F in which the channel region 24C is provided, the gate electrode 24G provided around the fin F, and the gate insulating film 241 provided between the gate electrode 24G and the fin F.

The fin F includes, for example, silicon (Si), etc. into which an n-type impurity is diffused. The fin F is provided on the surface 511B of the semiconductor substrate 11, substantially perpendicularly to the surface S11B. That is, the amplification transistor 24 having the Fin FET structure includes the n-type channel region 24C outside the semiconductor substrate 11 in which the photodiode 21 is provided. This makes it possible to increase the occupied area of the amplification transistor 24 while suppressing the influences on the occupied area of the photodiode 21. The impurity concentration of the channel region 24C is, for example, about 5×10¹⁷ cm⁻³ to 1×10¹⁹ cm⁻³. The fin F extends in the channel length direction (Y direction in FIG. 8). The fin F is provided with the source-drain regions 24A and 24B (FIG. 4A) adjacent to the channel region 24C. The source-drain regions 24A and 24B have the same electrical conductivity type (n-type) as the channel region 24C.

The gate electrode 24G, together with the fin F, is provided on the surface 511B of the semiconductor substrate 11. The gate electrode 24G includes the pair of the side faces 241 and 242 opposed with the fin F therebetween, and the upper face 243 that joins the pair of the side faces 241 and 242. The upper face 243 is opposed to the surface S11B of the semiconductor substrate 11, with the fin F in between. The gate electrode 24G includes, for example, p-type polysilicon, etc. Between the fin F and each of the pair of the side faces 241 and 242, and the upper face 234, the gate insulating film 241 is provided. The gate insulating film 241 includes, for example, silicon oxide (SiO), etc.

In the imaging element 10 according to the present modification example as well, as with the description given in the forgoing first embodiment, the amplification transistor 24 includes the channel region 24C of the same electrical conductivity type (n-type) as the electrical conductivity type of the source-drain regions 24A and 24B. Hence, it is possible to reduce the noise caused by the carriers trapped at the interface on the side of the channel region 24C on which the gate electrode 24G is disposed. Moreover, the channel region 24C (fin F) is provided outside the semiconductor substrate 11 in which the photodiode 21 is provided. This makes it possible to increase the occupied area of the amplification transistor 24. Hence, it is possible to suppress the noise more effectively.

### Modification Example 2

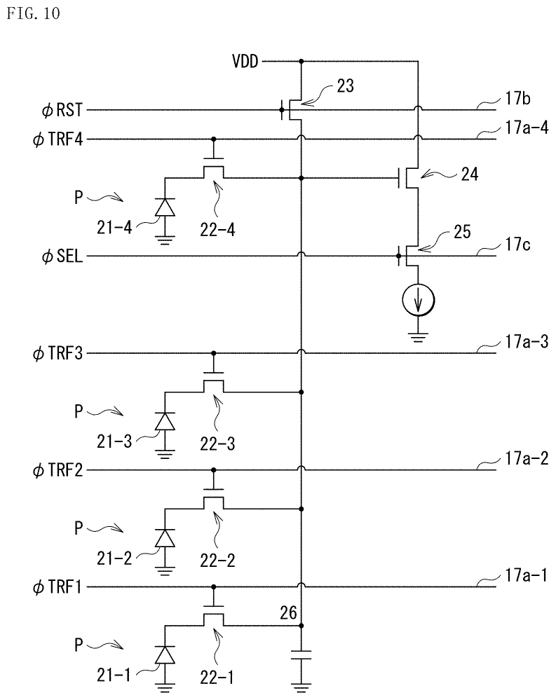

FIG. 9 illustrates a schematic cross-sectional configuration of a main portion of the imaging element 10 (FIG. 1) according to a modification example 2 of the forgoing first embodiment. FIG. 9 corresponds to the cross-sectional configuration along the B-B′ line in FIG. 3. The imaging element 10 includes the amplification transistor 24 having a GAA structure. Otherwise, the imaging element 10 according to the modification example 2 has the similar configuration to the imaging element 10 of the forgoing first embodiment, and has the similar workings and effects as well.

The amplification transistor 24 having the GAA structure includes a semiconductor section 24N in which the channel region 24C is provided, the gate electrode 24G surrounding the semiconductor section 24N, and the gate insulating film 241 provided between the gate electrode 24G and the semiconductor section 24N.

The semiconductor section 24N includes, for example, silicon (Si), etc. in which an n-type impurity is diffused. The semiconductor section 24N may include, for example, a nanowire. The semiconductor section 24N is provided on the surface S11B of the semiconductor substrate 11, and extends in the channel length direction (Y direction in FIG. 9). In a region surrounded by the gate electrode 24G of the semiconductor section 24N, the n-type channel region 24C is provided. In a region adjacent to the channel region 24C, the n-type source-drain regions 24A and 24B (FIG. 4A) are provided.

The gate electrode 24G, together with the semiconductor section 24N, is provided on the surface S11B of the semiconductor substrate 11. The gate electrode 24G includes the pair of the side faces 241 and 242 provided substantially perpendicular to the semiconductor substrate 11 (surface S11B), and the upper face 243 and a lower face 244 provided substantially parallel to the semiconductor substrate 11 (surface S11B). The pair of the side faces 241 and 242 is opposed, with the semiconductor section 24N therebetween. The upper face 243 and the lower face 244 join the pair of the side faces 241 and 242, and are opposed to each other with a nanowire therebetween. Out of the upper face 243 and the lower face 244, the lower face 244 is provided at a closer position to the semiconductor substrate 11. The gate electrode 24G includes, for example, p-type polysilicon, etc.

In the imaging element 10 according to the present modification example as well, as with the description in the forgoing first embodiment, the amplification transistor 24 includes the channel region 24C of the same electrical conductivity type (n-type) as the electrical conductivity type of the source-drain regions 24A and 24B. Hence, it is possible to reduce the noise caused by the carriers trapped at the interface on the side of the channel region 24C on which the gate electrode 24G is disposed. Moreover, the channel region 24C (semiconductor section 24N) is provided outside the semiconductor substrate 11 in which the photodiode 21 is provided. This makes it possible to increase the occupied area of the amplification transistor 24. Hence, it is possible to suppress the noise more effectively.

### Modification Example 3

FIG. 10 illustrates an example of a configuration of an equivalent circuit of the imaging element 10 (FIG. 1) according to a modification example 3 of the forgoing first embodiment. In this imaging element 10, the amplification transistor 24, etc. is shared by a plurality of the pixels P. Otherwise, the imaging element 10 according to the modification example 3 has the similar configuration to the imaging element 10 of the forgoing first embodiment, and has the similar workings and effects as well.

In the imaging element 10, the FD section 26, the reset transistor 23, the amplification transistor 24, and the selection transistor 25 are shared by, for example, the four pixels P.

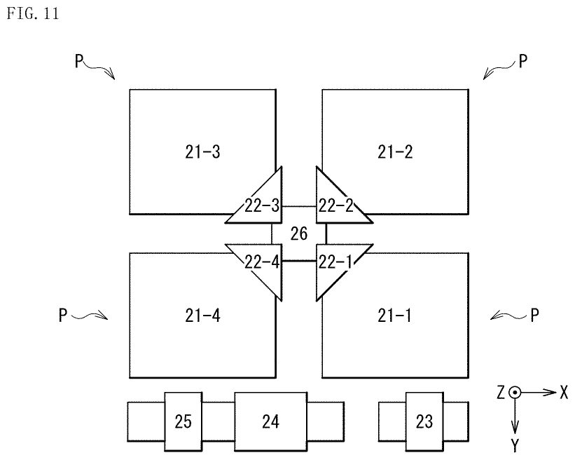

FIG. 11 illustrates a schematic plan configuration of the four pixels P, and the FD section 26, the reset transistor 23, the amplification transistor 24, and the selection transistor 25 shared by the four pixels P. A configuration of the imaging element 10 of the present modification example is described using FIG. 11, together with FIG. 10.

The photodiode (any one of photodiodes 21-1, 21-2, 21-3, and 21-4) is provided in a corresponding one of the four pixels P. The photodiode 21-1 is coupled to the transfer transistor 22-1. The photodiode 21-2 is coupled to the transfer transistor 22-2. The photodiode 21-3 is coupled to the transfer transistor 22-4. That is, in the single pixel P, the single photodiode (any one of the photodiodes 21-1, 21-2, 21-3, and 21-4) and the single transfer transistor (any one of the transfer transistors 22-1, 22-2, 22-3, and 22-4) are disposed. The gate electrodes of the transfer transistors 22-1, 22-2, 22-3, and 22-4 are configured to be supplied, respectively, with the transfer pulse φTRF1, φTRF2, φTRF3, and φTRF4 through the transfer lines 17a-1, 17a-2, 17a-3, and 17a-4 (FIG. 10).

The FD section 26 is provided in the central portion of the four pixels P (FIG. 11). The signal electric charges photoelectrically converted in each of the photodiodes 21-1, 21-2, 21-3, and 21-4 are transferred to the FD section 26 through the transfer transistors 22-1, 22-2, 22-3, and 22-4.

The reset transistor 23, the amplification transistor 24, and the selection transistor 25 are arranged side by side, for example, along an end of the four pixels P that share the transistors (e.g., along the end in the X direction in FIG. 11). The configuration of the amplification transistor 24 is, for example, similar to that described in the forgoing first embodiment (see FIGS. 4A and 4B). Alternatively, the configuration of the amplification transistor 24 may be similar to that described in the modification example 1 (FIG. 8) or the modification example 2 (FIG. 9).

In the imaging element 10 according to the present modification example as well, as with the description in the forgoing first embodiment, the amplification transistor 24 includes the channel region 24C of the same electrical conductivity type (n-type) as the electrical conductivity type of the source-drain regions 24A and 24B. Hence, it is possible to reduce the noise due to the carriers trapped at the interface on the side of the channel region 24C on which the gate electrode 24G is disposed.

### Second Embodiment

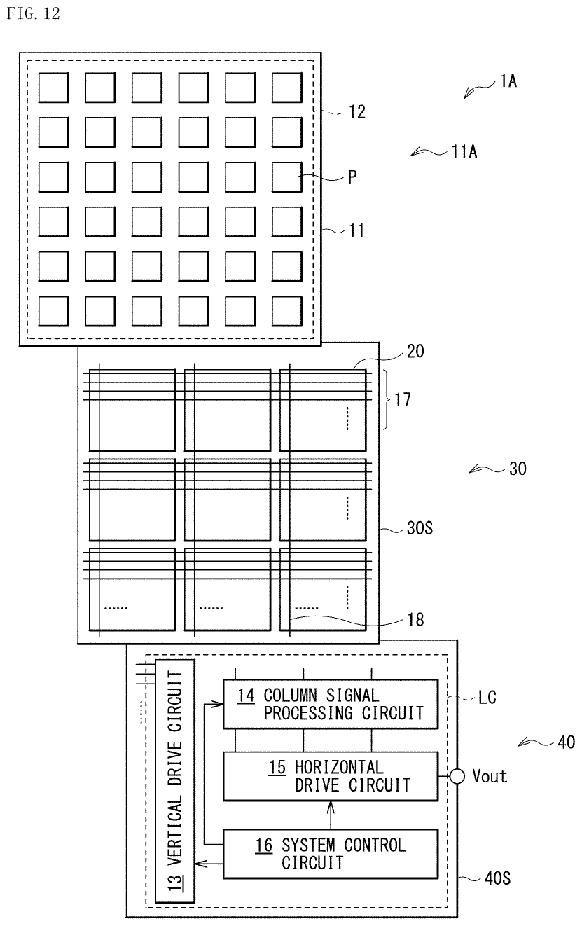

FIG. 12 illustrates a schematic configuration of a solid-state imaging element (imaging element 10A) according to a second embodiment of the present disclosure. The imaging element 10A includes a stacked structure of a first substrate 11A, a second substrate 30, and a third substrate 40. On the first substrate 11A, the photodiode 21, etc. is provided. On the second substrate 30, the readout circuit 20 (specifically, the amplification transistor 24 and the selection transistor 25) are provided. On the third substrate 40, a logic circuit (drive circuit) is provided. Otherwise, the imaging element 10A of the second embodiment has the similar configuration to the imaging element 10 of the forgoing first embodiment, and has the similar workings and effects as well. Here, specific examples of the output transistor of the present disclosure are the amplification transistor 24 and the selector transistor 25.

In the imaging element 10A, the first substrate 11A, the second substrate 30, and the third substrate 40 are stacked in this order. The imaging element 10A is configured to allow light to enter from side on which the first substrate 11A is disposed. That is, the imaging element 10A is an imaging element of the backside illumination type.

The first substrate 11A includes, on the semiconductor substrate 11, the plurality of the pixels P that performs the photoelectric conversion. The second substrate 30 includes, on a semiconductor layer 30S, the readout circuits 20 each of which is provided, for example, for every four pixels P. The second substrate 30 includes the pixel drive lines 17 and the vertical signal lines 18. The third substrate 40 includes, in a semiconductor layer 40S, a logic circuit LC that performs processing on the pixel signal. The logic circuit LC includes, for example, the vertical drive circuit 13, the signal processing circuit 14, the horizontal drive circuit 15, and the system control circuit 16. The logic circuit LC (specifically, the horizontal drive circuit 15) outputs an output voltage Vout for each pixel P to outside. In the logic circuit LC, for example, a low-resistance region including a silicide such as CoSi₂ or NiSi may be formed in a front surface of an impurity diffusion region in contact with a source electrode and a drain electrode. The silicide is formed with the use of a salicide (Self Aligned Silicide) process.

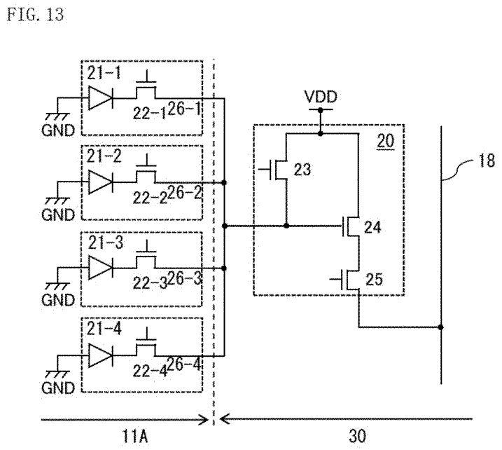

FIG. 13 illustrates an example of the pixel P and the readout circuit 20. In the following, description is given of a case where the four pixels P share the single readout circuit 20, as illustrated in FIG. 13. Here, “share” means that outputs of the four pixels P are inputted to the common readout circuit 20.

The pixels P each include common constituent elements. In FIG. 13, to distinguish the constituent elements of the respective pixels P from one another, identification numbers (1, 2, 3, and 4) are attached to ends of reference numerals of the constituent elements of the respective pixels P. In the following, in a case where it is necessary to distinguish the constituent elements of the respective pixels P from one another, the identification numbers are attached to the ends of the reference numerals of the constituent elements of the respective pixels P, but in a case where it is not necessary to distinguish the constituent elements of the respective pixels P from one another, the identification numbers at the ends of the reference numerals of the constituent elements of the respective pixels P are omitted.

Each of the pixels P includes, for example, the photodiode 21, the transfer transistor 22, and the FD section 26. The transfer transistor 22 is electrically coupled to the photodiode 21. The FD section 26 temporarily holds the electric charges outputted from the photodiode 21 through the transfer transistor 22. The photodiode 21 performs the photoelectric conversion to generate the electric charges corresponding to the amount of received light. The cathode of the photodiode 21 is electrically coupled to the source of the transfer transistor 22, and the anode of the photodiode 21 is electrically coupled to a reference potential line (for example, ground). The drain of the transfer transistor 22 is electrically coupled to the FD section 26, and the gate of the transfer transistor 22 is electrically coupled to the pixel drive line 17. The transfer transistor 22 is, for example, a CMOS (Complementary Metal Oxide Semiconductor) transistor.

The FD sections 26 of the respective pixels P sharing the single readout circuit 20 are electrically coupled to one another and electrically coupled to an input terminal of the common readout circuit 20. The readout circuit 20 includes, for example, the reset transistor 23, the selection transistor 25, and the amplification transistor 24. It should be noted that the selection transistor 25 may be omitted as necessary. The source of the reset transistor 23 (input terminal of the readout circuit 20) is electrically coupled to the FD section 26, and the drain of the reset transistor 23 is electrically coupled to a power supply line VDD and the drain of the amplification transistor 24. The gate of the reset transistor 23 is electrically coupled to the pixel drive line 17 (see FIG. 12). The source of the amplification transistor 24 is electrically coupled to the drain of the selection transistor 25, and the gate of the amplification transistor 24 is electrically coupled to the source of the reset transistor 23. The source of the selection transistor 25 (output terminal of the readout circuit 20) is electrically coupled to the vertical signal line 18, and the gate of the selection transistor 25 is electrically coupled to the pixel drive line 17 (see FIG. 12).

In a case where the transfer transistor 22 is turned on, the transfer transistor 22 transfers the electric charges of the photodiode 21 to the FD section 26. The reset transistor 23 resets the potential of the FD section 26 to a predetermined potential. In a case where the reset transistor 23 is turned on, the potential of the FD section 26 is reset to a potential of the power supply line VDD. The selection transistor 25 controls output timing of the pixel signal from the readout circuit 20. The amplification transistor 24 generates, as the pixel signal, a signal of a voltage corresponding to a level of the electric charges held in the FD section 26. The amplification transistor 24 constitutes a source follower amplifier, and outputs the pixel signal of a voltage corresponding to a level of the electric charges generated by the photodiode 21. In a case where the selection transistor 25 is turned on, the amplification transistor 24 amplifies the potential of the FD section 26 and outputs a voltage corresponding to the relevant potential to the signal processing circuit 14 through the vertical signal line 18. The reset transistor 23, the amplification transistor 24, and the selection transistor 25 are, for example, CMOS transistors.

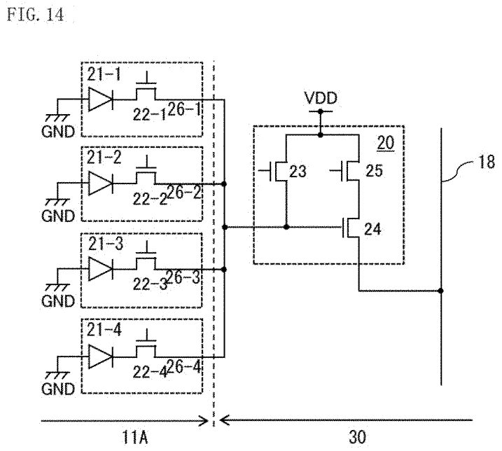

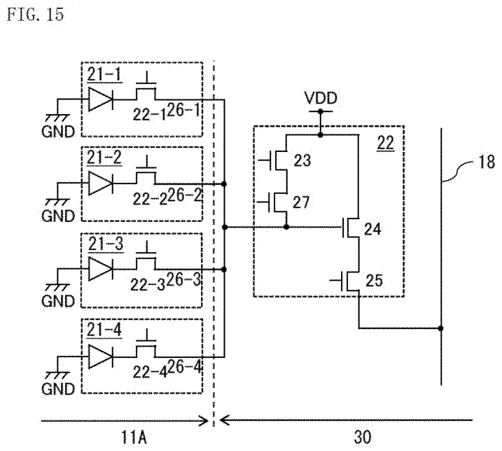

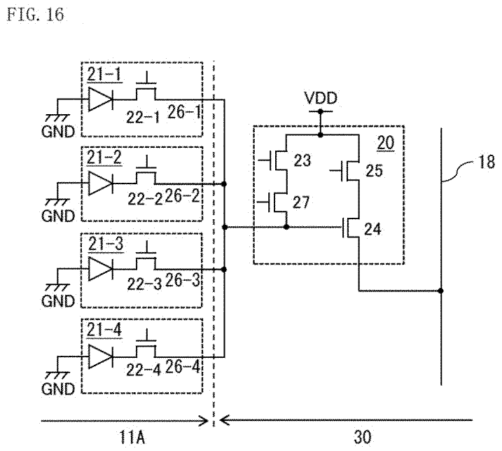

It should be noted that, as illustrated in FIG. 14, the selection transistor 25 may be provided between the power supply line VDD and the amplification transistor 24. In this case, the drain of the reset transistor 23 is electrically coupled to the power supply line VDD and the drain of the selection transistor 25. The source of the selection transistor 25 is electrically coupled to the drain of the amplification transistor 24, and the gate of the selection transistor 25 is electrically coupled to the pixel drive line 17 (see FIG. 1). The source of the amplification transistor 24 (output terminal of the readout circuit 20) is electrically coupled to the vertical signal line 18, and the gate of the amplification transistor 24 is electrically coupled to the source of the reset transistor 23. In addition, as illustrated in FIGS. 15 and 16, an FD transfer transistor 27 may be provided between the source of the reset transistor 23 and the gate of the amplification transistor 24.

The FD transfer transistor 27 is used to switch conversion efficiency. In general, the pixel signal is small in photographing in a dark place. In a case where conversion from electric charges into a voltage is performed on the basis of Q=CV, a large capacitance (FD capacitance C) of the FD section 26 causes V to become small on the occasion of the conversion into the voltage by the amplification transistor 24. In contrast, in a bright place, the pixel signal becomes large, and accordingly, in a case where the FD capacitance C is not large, the FD section 26 fails in receiving the electric charges of the photodiode 21. Furthermore, to prevent V from becoming excessively large (in other words, to make V small) on the occasion of the conversion into the voltage by the amplification transistor 24, it is necessary for the FD capacitance C to be large. In consideration of these, in a case where the FD transfer transistor 27 is turned on, there is an increase by a gate capacitance of the FD transfer transistor 27, resulting in an increase the entire FD capacitance C. In contrast, in a case where the FD transfer transistor 27 is turned off, the entire FD capacitance C becomes small. Thus, turning on and off the FD transfer transistor 27 makes it possible to make the FD capacitance C variable and switch the conversion efficiency.

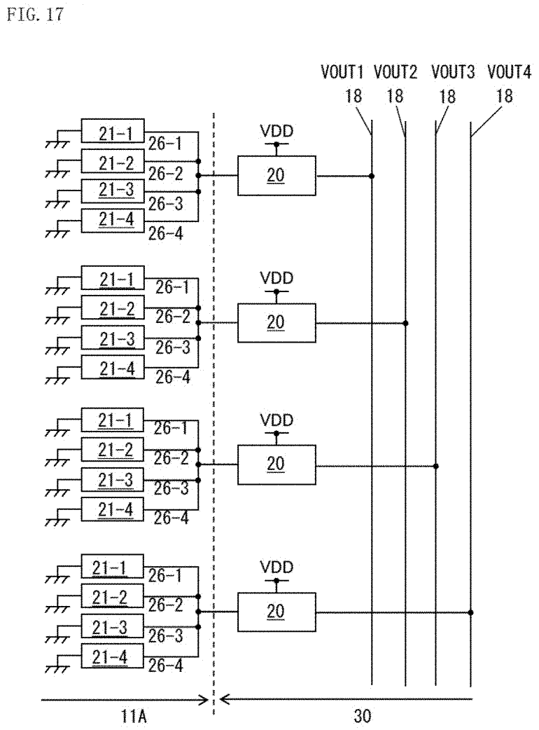

FIG. 17 illustrates an example of a coupling mode between a plurality of the readout circuits 20 and a plurality of the vertical signal lines 18. In a case where the plurality of the readout circuits 20 are disposed side by side in an extending direction (for example, the column direction) of the vertical signal lines 18, the plurality of the vertical signal lines 18 may be assigned one by one to respective ones of the readout circuits 20. For example, as illustrated in FIG. 17, in a case where the four readout circuits 20 are disposed side by side in the extending direction (for example, the column direction) of the vertical signal lines 18, the four vertical signal lines 18 may be assigned one by one to respective ones of the readout circuits 20. It should be noted that, in FIG. 17, to distinguish each of the vertical signal lines 18, identification numbers (1, 2, 3, and 4) are attached to ends of reference numerals of the respective vertical signal lines 18.

FIG. 18 illustrates an example of a cross-sectional configuration in a vertical direction of the imaging element 10A. The first substrate 11A includes the semiconductor substrate 11 and an interlayer insulating film 19 on the semiconductor substrate 11. The second substrate 30 is provided to be opposed to the first substrate 11A and includes the semiconductor layer 30S, an interlayer insulating film 301, and a multilayer wiring layer 30W in this order from side on which the first substrate 11A (the interlayer insulating film 19) is disposed. The third substrate 40 includes a multilayer wiring layer 40W, an interlayer insulating film 401, and the semiconductor layer 40S in this order from side on which the second substrate 30 (the multilayer wiring layer 30W) is disposed. A bonding surface S is provided between the multilayer wiring layer 30W of the second substrate 30 and the multilayer wiring layer 40W of the third substrate 40.

In the semiconductor substrate 11, for example, the photodiode 21 and the FD section 26 are provided. The FD section 26 is provided in the vicinity of the surface S11B inside the semiconductor substrate 11. The FD section 26 includes, for example, an impurity diffusion region in which an n-type impurity is diffused in the p-type well region 111. The concentration of the n-type impurity of the FD section 26 is, for example, about 1×10¹⁹ cm⁻³ to 1×10²⁰ cm⁻³. The surface S11A of the semiconductor substrate 11 serves as a light-entering surface.

In the vicinity of the surface S11B of the semiconductor substrate 11, together with the FD section 26, the transfer transistor 22 is provided. The transfer transistor 22 includes, for example, a gate electrode 22G and a gate insulating film 221. The gate electrode 22G is provided to be opposed to the semiconductor substrate 11, outside the semiconductor substrate 11. The gate electrode 22G includes, for example, p-type polysilicon, etc. The gate electrode 22G may include a metal such as tungsten (W), titanium (Ti), titanium nitride (TiN), hafnium (Hf), hafnium silicide (HfSi), ruthenium (Ru), iridium (Ir), and cobalt (Co). The gate insulating film 221 is provided between the gate electrode 22G and the semiconductor substrate 11. The gate insulating film 221 includes, for example, a silicon oxide film (SiO), etc. The gate insulating film 221 may include a high-dielectric insulating material such as hafnium oxide (HfO₂), hafnium silicate (HfSiO), tantalum oxide (Ta₂O₅), and hafnium aluminate (HfAlO). The gate electrode 22G and the gate insulating film 221 are covered with the interlayer insulating film 19. The interlayer insulating film 19 includes, for example, silicon oxide (SiO), etc.

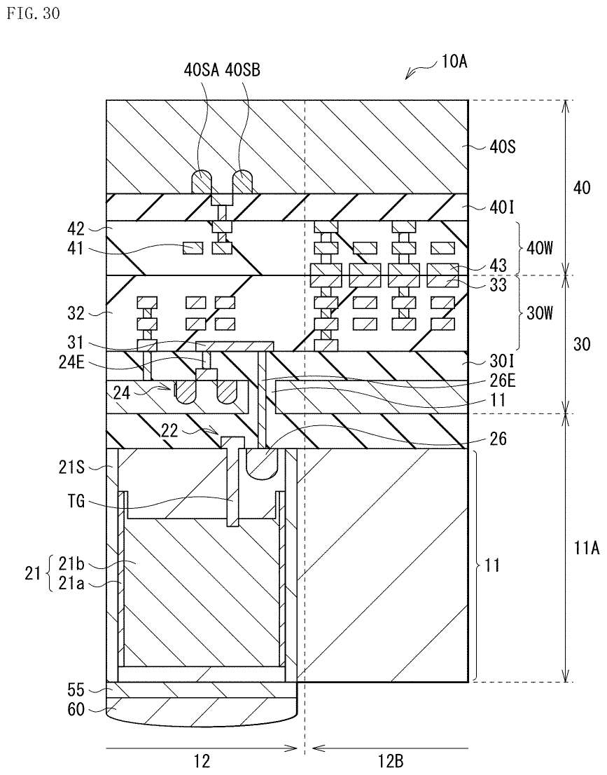

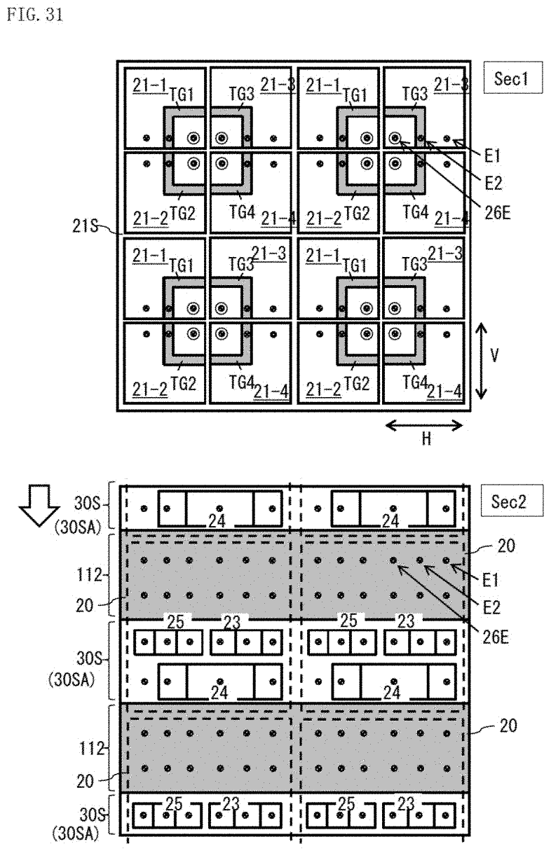

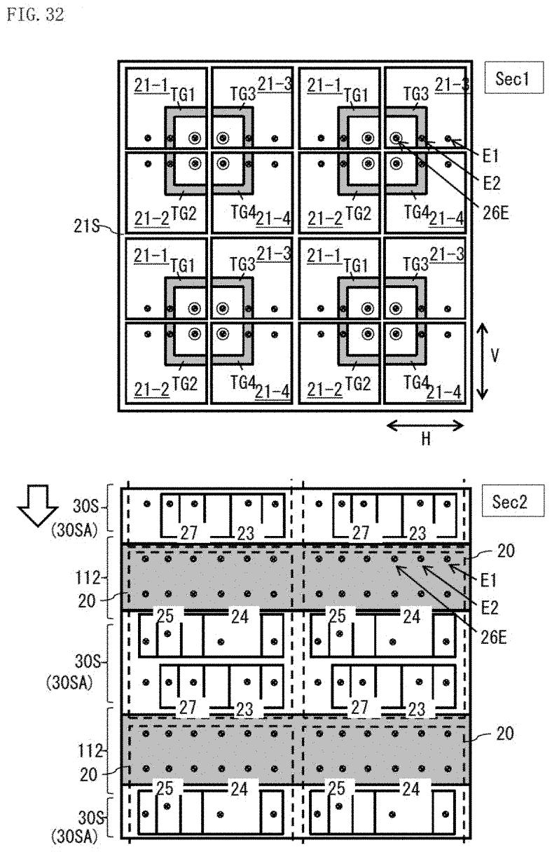

The first substrate 11A may further include, for example, a fixed electric charge film in contact with the surface S11A of the semiconductor substrate 11. The fixed electric charge film is negatively charged to suppress generation of a dark current caused by an interface level on light-receiving-surface side of the semiconductor substrate 11. The fixed electric charge film includes, for example, an insulating film including negative fixed electric charges. Examples of a material of such an insulating film include hafnium oxide, zirconium oxide, aluminum oxide, titanium oxide, or tantalum oxide. A hole accumulation layer is formed at an interface on side of the semiconductor substrate 11 on which the light-receiving surface is disposed, by an electric field induced by the fixed electric charge film. This hole accumulation layer suppresses generation of electrons from the interface. The imaging element 10A includes, for example, a color filter (e.g., color filter 55 in FIG. 30) and light-receiving lens (e.g., light-receiving lens 60 in FIG. 30), on the light-entering side of the first substrate 11A. The color filter is provided on the side of the semiconductor substrate 11 on which the surface S11A is disposed. The color filter is provided, for example, in contact with the fixed electric charge film, and is provided at a position opposed to the pixel P with the fixed electric charge film interposed therebetween. The light-receiving lens is provided, for example, in contact with the color filter, and is provided at a position opposed to the pixel P with the color filter and the fixed electric charge film interposed therebetween.

The semiconductor layer 30S of the second substrate 30 is opposed to the semiconductor substrate 11 with the interlayer insulating film 19 in between. The semiconductor layer 30S includes a silicon (Si) layer having a thickness (size in the Z direction in FIG. 12) of 20 nm to 200 nm. In the semiconductor layer 30S, for example, the channel regions 24C and 25C, and the source-drain regions 24A, 24B, 25A, and 25B of the amplification transistor 24 and the selection transistor 25, respectively, are provided.

The pair of the source-drain regions 24A and 24B of the amplification transistor 24 is n-type impurity diffusion regions provided in the semiconductor layer 30S, and is provided, for example, over a portion in the thickness direction (Z direction in FIG. 18) of the semiconductor layer 30S from the side on which the interlayer insulating film 301 is disposed. The channel region 24C is provided between the pair of the source-drain regions 24A and 24B. As with the description in the forgoing first embodiment, the channel region 24C of the amplification transistor 24 has the same electrical conductivity type (n-type) as the source-drain regions 24A and 24B. The channel region 24C is provided, for example, over an entirety in the thickness direction of the semiconductor layer 30S.

The selection transistor 25 is disposed, for example, at a position adjacent to the amplification transistor 24 in the channel length direction (Y direction in FIG. 18). One of the pair of the source-drain regions 25A and 25B (source-drain region 25B) of the selection transistor 25 is adjacent to one of the pair of the source-drain regions 24A and 24B (source-drain region 24A) of the amplification transistor 24, and these may be shared. The pair of the source-drain regions 25A and 25B of the selection transistor 25 is n-type impurity diffusion regions provided in the semiconductor layer 30S, and is provided, for example, over a portion in the thickness direction of the semiconductor layer 30S from the side on which the interlayer insulating film 301 is disposed. The channel region 25C is provided between the pair of the source-drain regions 25A and 25B. The channel region 25C of the selection transistor 25 has, for example, the same electrical conductivity type (n-type) as the source-drain regions 25A and 25B. The channel region 24C is provided, for example, over an entirety in the thickness direction of the semiconductor layer 30S.

In the imaging element 10A of stacked type, the channel regions 24C and 25C of the amplification transistor 24 and the selection transistor 25, etc., are provided in the semiconductor layer 30S separate from the semiconductor substrate 11 in which the photodiode 21 and the FD section 26 are provided. This makes it possible to increase the occupied area of the amplification transistor 24 and the selection transistor 25, making it possible to suppress the generation of the noise more effectively. Moreover, the amplification transistor 24 and the selection transistor 25 are manufactured separately from the photodiode 21, etc. This makes it easier to optimize a temperature in manufacturing the amplification transistor 24 and the selection transistor 25. Hence, it is possible to suppress the generation of the noise effectively in terms of a manufacturing process as well.

It suffices that at least the channel region 24C of the amplification transistor 24 or the channel region 25C of the selection transistor 25 has the same electrical conductivity type as the electrical conductivity type of the source-drain regions 24A, 24B, 25A, and 25B. For example, the channel region 25C of the selection transistor 25 may be a p-type impurity diffusion region.

In the semiconductor layer 30S, the element isolation regions 112 are provided. The element isolation regions 112 are provided around the channel regions 24C and 25C, and the pair of the source-drain regions 24A, 24B, 25A, and 25B. Thus, the plurality of the transistors are electrically isolated.

The amplification transistor 24 includes the gate electrode 24G and the gate insulating film 241, in addition to the channel region 24C and the pair of the source-drain regions 24A and 24B. The selection transistor 25 includes the gate electrode 25G and the gate insulating film 251, in addition to the channel region 25C and the source-drain regions 25A and 25B.

The amplification transistor 24 and the selection transistor 25 are, for example, transistors of planar (planer) type. The gate electrodes 24G and 25G are provided outside the semiconductor layer 30S, and include a single plane opposed to respective ones of the channel regions 24C and 25C. That is, the gate electrodes 24G and 25G each have a flat plate shape. For example, in a case where the semiconductor layer 30S is formed using an SOI substrate (SOI substrate 50 in FIG. 15B to be described later), etc., and a thickness of the semiconductor layer 30S is small, it is easier to constitute a junction-less transistor of the planar type. The gate electrodes 24G and 25G include, for example, p-type polysilicon, etc. The gate electrodes 24G and 25G may include a metal such as tungsten (W), titanium (Ti), titanium nitride (TiN), hafnium (Hf), hafnium silicide (HfSi), ruthenium (Ru), iridium (Ir), and cobalt (Co).

The gate insulating films 241 and 251 are provided respectively between the gate electrodes 24G and 25G, and the semiconductor layer 30S. The gate insulating films 241 and 251 each include, for example, a silicon oxide film (SiO), etc. The gate insulating films 241 and 251 may include a high-dielectric insulating material such as hafnium oxide (HfO₂), hafnium silicate (HfSiO), tantalum oxide (Ta₂O₅), and hafnium aluminate (HfAlO).

The gate electrodes 24G and 25G, and the gate insulating films 241 and 251 are covered with the interlayer insulating film 301. The interlayer insulating film 301 includes, for example, silicon oxide (SiO), etc. The interlayer insulating film 301 is provided with a connection hole reaching the gate electrode 24G of the amplification transistor 24, and a connection hole that penetrates the interlayer insulating film 301, the semiconductor layer 30S, and the interlayer insulating film 19 to reach the FD section 26. The connection hole reaching the gate electrode 24G is provided with an electrode 24E. The connection hole reaching the FD section 26 is provided with an electrode 26E.

The multilayer wiring layer 30W is opposed to the semiconductor layer 30S, with the interlayer insulating film 301 in between. The multilayer wiring layer 30W includes a plurality of wirings 31, an interlayer insulating film 32, and a contact electrode 33. The wiring 31 includes, for example, a metal material such as copper (Cu) or aluminum (Al), etc. The electrode 24E and the electrode 26E are coupled to each other through the wiring 31. That is, the gate electrode 24G of the amplification transistor 24 is coupled to the FD section 26 through the wiring 31. The wiring 31 is electrically coupled to, for example, the reset transistor 23 (FIG. 2). The interlayer insulating film 32 is provided for separation between the plurality of the wirings 31, and includes, for example, silicon oxide (SiO), etc. The contact electrode 33 is provided for, for example, electrical coupling between the wirings 31 of the multilayer wiring layer 30W and the multilayer wiring layer 40W (specifically, a contact electrode 43 to be described later). The contact electrode 33 includes, for example, copper (Cu), and one surface is exposed from the bonding surface S.

In the semiconductor layer 40S of the third substrate 40, for example, a channel region 40SC and a pair of source-drain regions 40SA and 40SB of a plurality of transistors Tr are provided. The plurality of transistors Tr form, for example, a logic circuit. To the logic circuit, signal electric charges are outputted from the photodiode 21 through the amplification transistor 24 and the selection transistor 25. Thus, in the imaging element 10A, the logic circuit LC is provided on a separate substrate (third substrate 40) from the semiconductor substrate 11 in which the photodiode 21, etc. is provided. The separate substrate and the semiconductor substrate 11 are stacked. Hence, it is possible to reduce a chip size.

Each of the plurality of the transistors Tr includes a gate electrode 40IG and a gate insulating film 4011, in addition to the channel region 40SC and the pair of the source-drain regions 40SA and 40SB. The gate electrode 40IG of each of the plurality of the transistors Tr is provided, for example, outside the semiconductor layer 40S, and each include a single plane opposed to the channel region 40SC. The gate insulating film 4011 is provided between the gate electrode 40IG and the semiconductor layer 40S. The gate electrode 40IG and the gate insulating film 4011 is covered with the interlayer insulating film 401.

The multilayer wiring layer 40W of the third substrate 40 is opposed to the semiconductor layer 40S, with the interlayer insulating film 401 in between. Between the multilayer wiring layer 40W and the multilayer wiring layer 30W of the second substrate 30, the bonding surface S is formed. The multilayer wiring layer 40W includes a plurality of wirings 41, an interlayer insulating film 42, and the contact electrode 43. The wiring 41 includes, for example, a metal material such as copper (Cu) or aluminum (Al), etc. The interlayer insulating film 42 is provided for separation between the plurality of the wirings 41, and includes, for example, silicon oxide (SiO), etc. The contact electrode 43 is provided for, for example, electrical coupling between the wiring 41 of the multilayer wiring layer 40W and the contact electrode 33 of the multilayer wiring layer 30W. The contact electrode 43 includes, for example, copper (Cu), and one surface is exposed from the bonding surface S, in contact with the contact electrode 33. That is, the third substrate 40 and the second substrate 30 are coupled by Cu—Cu bonding.

In the imaging element 10A of the second embodiment as well, as with the description in the forgoing first embodiment, the amplification transistor 24 includes the channel region 24C of the same electrical conductivity type (n-type) as the electrical conductivity type of the source-drain regions 24A and 24B. Hence, it is possible to reduce the noise caused by the carriers trapped at the interface on the side of the channel region 24C on which the gate electrode 24G is disposed. Moreover, the selection transistor 25 also includes the channel region 25C of the same electrical conductivity type (n-type) as the electrical conductivity type of the source-drain regions 25A and 25B. Hence, it is possible to reduce the noise caused by the carriers trapped at the interface on the side of the channel region 25C on which the gate electrode 25G is disposed.

Furthermore, the imaging element 10A has the stacked structure of the first substrate 11A, the second substrate 30, and the third substrate 40. Thus, the amplification transistor 24 and the selection transistor 25 are formed on the separate substrate (second substrate 30) from the first substrate 11A in which the photodiode 21 and the FD section 26 are provided. Hence, it is possible to increase the occupied area of the amplification transistor 24 and the selection transistor 25, making it possible to suppress the noise more effectively. Moreover, in terms of the manufacturing process as well, it is possible to optimize a manufacturing temperature of the amplification transistor 24 and the selection transistor 25, making it possible to suppress the generation of the noise.

In addition, the third substrate 40 including the logic circuit LC is stacked on the first substrate 11A in which the photodiode 21, etc., is provided. Hence, it is possible to reduce the chip size.

### Modification Example 4

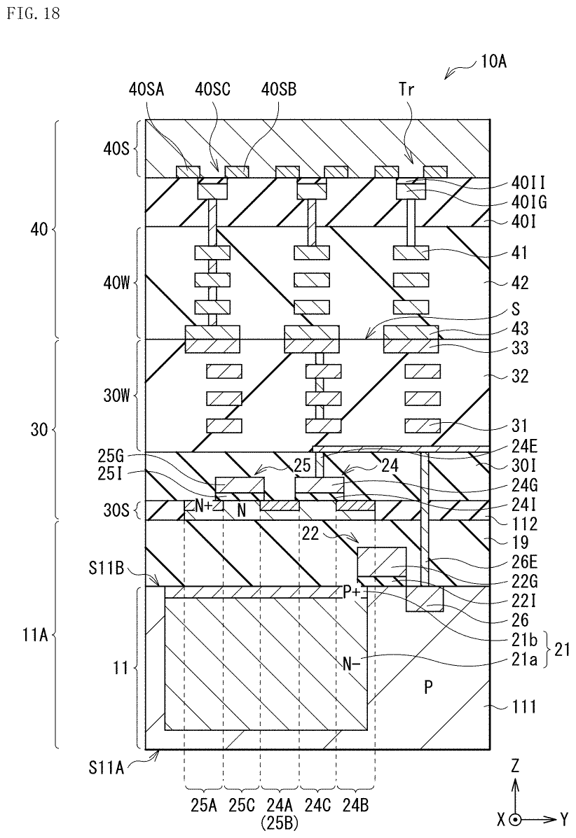

FIGS. 19, 20A, and 20B illustrate a schematic configuration of a main portion of the imaging element 10A (FIG. 18) according to a modification example (modification example 4) of the forgoing second embodiment. FIG. 19 illustrates a plan configuration of the reset transistor 23, the amplification transistor 24, and the selection transistor 25. FIGS. 20A and 20B illustrate a cross-sectional configuration along an A-A′ line illustrated in FIG. 19, and a cross-sectional configuration along a B-B′ line illustrated in FIG. 19, respectively. The reset transistor 23, the amplification transistor 24, and the selection transistor 25 of the imaging element 10A have the Fin FET structure. Otherwise, the imaging element 10A of the modification example 4 has the similar configuration to the imaging element 10A of the forgoing second embodiment, and has the similar workings and effects as well.

The reset transistor 23 having the Fin FET structure includes a fin F1 in which a channel region 23C is provided, a gate electrode 23G provided around the fin F1, and a gate insulating film 231 provided between the gate electrode 23G and the fin F1 (FIGS. 19 and 20A). The amplification transistor 24 having the Fin FET structure includes fins F2 and F3 in which the channel region 24C is provided, the gate electrode 24G provided around the fins F2 and F3, and the gate insulating film 241 provided between the gate electrode 24G and the fins F2 and F3 (FIGS. 19 and 20A). The selection transistor 25 having the Fin FET structure includes the fins F2 and F3 in which the channel region 25C is provided, the gate electrode 25G provided around the fins F2 and F3, and the gate insulating film 251 provided between the gate electrode 25G and the fins F2 and F3 (FIGS. 19 and 20B).

The fins F1, F2, and F3 include, for example, silicon (Si), etc. in which an n-type impurity is diffused. For example, the fins F1, F2, and F3 include silicon having an impurity concentration of the n-type impurity of about 1×10¹⁷ cm⁻³ to 1×10¹⁹ cm⁻³. The fins F1, F2, and F3 are provided on the interlayer insulating film 19 substantially perpendicularly to the surface S11B of the semiconductor substrate 11. The fins F1, F2, and F3 constitute the semiconductor layer 30S of the second substrate 30. The fins F1, F2, and F3 extend, for example, parallel to one another. The fins F1, F2, and F3 are separated from one another by the element isolation regions 112. The fins F2 and F3 are connected to each other at both ends.

In the fin F1, the source-drain regions 23A and 23B adjacent to the channel region 23C are provided. In the fins F2 and F3, the source-drain regions 24A and 25B adjacent to the channel region 24C, and the source-drain regions 25A and 25B adjacent to the channel region 25C are provided. That is, the reset transistor 23 includes, in the fin F1 outside the semiconductor substrate 11, the n-type source-drain regions 23A and 23B, and the channel region 23C of the same electrical conductivity type (n-type) as the source-drain regions 23A and 23B. The amplification transistor 24 includes, in the fins F2 and F3, the n-type source-drain regions 24A and 24B, and the channel region 24C of the same electrical conductivity type (n-type) as the source-drain regions 24A and 24B. The selection transistor 25 includes, for example, in the same fins F2 and F3 as the amplification transistor 24, the n-type source-drain regions 25A and 25B, and the channel region 25C of the same electrical conductivity type (n-type) as the source-drain regions 25A and 25B. In other words, in the fins F2 and F3, a plurality of the channel regions 24C and 25C, and the source-drain regions 24A, 24B, 25A, and 25B are provided continuously.

At one end of the fins F2 and F3, a contact section FC1 is provided. At the other end of the fins F2 and F3, a contact section FC2 is provided. The contact section FC1 is a section that couples one of the pair of the source-drain regions 24A and 24B (source-drain region 24B) of the amplification transistor 24 to the pixel power supply Vdd. The contact section FC2 is a section that couples one of the pair of the source-drain regions 25A and 25B (source-drain region 25A) of the selection transistor 25 to the vertical signal line 18 (FIG. 2).

The gate electrode 23G is provided, together with the fin F1, on the interlayer insulating film 19. The gate electrode 23G includes a pair of side faces 231 and 232 opposed to each other with the fin F1 therebetween, and an upper face 233 that joints the pair of the side faces 231 and 232. The upper face 233 is opposed to the interlayer insulating film 19 with the fin F1 therebetween. The upper face 233 is covered with the interlayer insulating film 301. Between the fin F1 and each of the pair of the side faces 231 and 232, and the upper face 233, the gate insulating film 231 is provided.

The gate electrode 24G is provided, together with the fins F2 and F3, on the interlayer insulating film 19. The gate electrode 24G includes the pair of the side faces 241 and 242 opposed to each other with the fins F2 and F3 therebetween, the upper face 243 that joints the pair of the side faces 241 and 242, and a separation face 245 between the fin F2 and the fin F3. The pair of the side faces 241 and 242, and the separation face 245 are provided in parallel with one another. The upper face 243 is opposed to the interlayer insulating film 19 with the fins F2 and F3 therebetween. The upper face 243 is covered with the interlayer insulating film 301. Between the fins F2 and F3, and each of the pair of the side faces 241 and 242, the upper face 233, and the separation face 235, the gate insulating film 241 is provided.

The gate electrode 25G is provided, together with the fins F2 and F3, on the interlayer insulating film 19. The gate electrode 25G includes a pair of side faces 251 and 252 opposed to each other with the fins F2 and F3 therebetween, an upper face 253 that joints the pair of the side faces 251 and 252, and a separation face 255 between the fin F2 and the fin F3. The pair of the side faces 251 and 252, and the separation face 255 are provided in parallel with one another. The upper face 253 is opposed to the interlayer insulating film 19 with the fins F2 and F3 therebetween. The upper face 253 is covered with the interlayer insulating film 301. Between the fins F2 and F3, and each of the pair of the side faces 251 and 252, the upper face 253, and the separation face 255, the gate insulating film 251 is provided.

The gate electrodes 23G, 24G, and 25G as described above include, for example, p-type polysilicon, etc. The gate insulating films 231, 241, and 251 includes, for example, silicon oxide (SiO), etc.

The interlayer insulating film 301 is opposed to the interlayer insulating film 19 with the fins F1, F2, and F3 therebetween. The interlayer insulating film 301 is provided with a connection hole reaching the upper faces 243 and 253 of the gate electrodes 24G and 25G, and a connection hole reaching the fin F1. The connection hole reaching the upper face 243 is provided with the electrode 24E. The connection hole reaching the upper face 253 is provided with an electrode 25E. The connection hole reaching the fin F1 is provided with an electrode 23E.

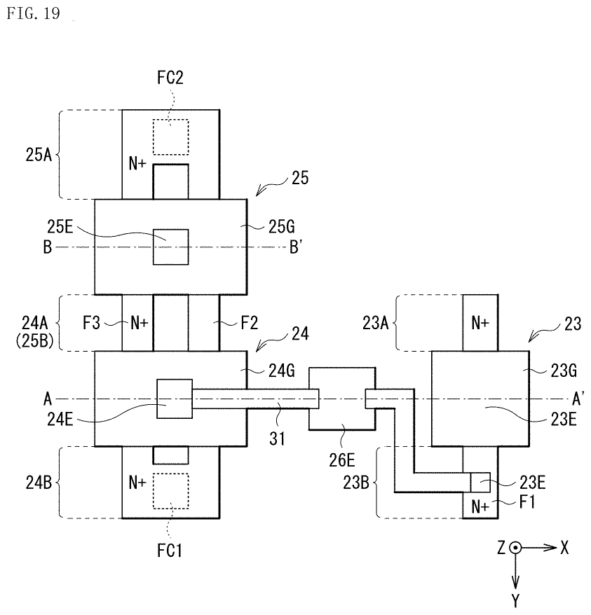

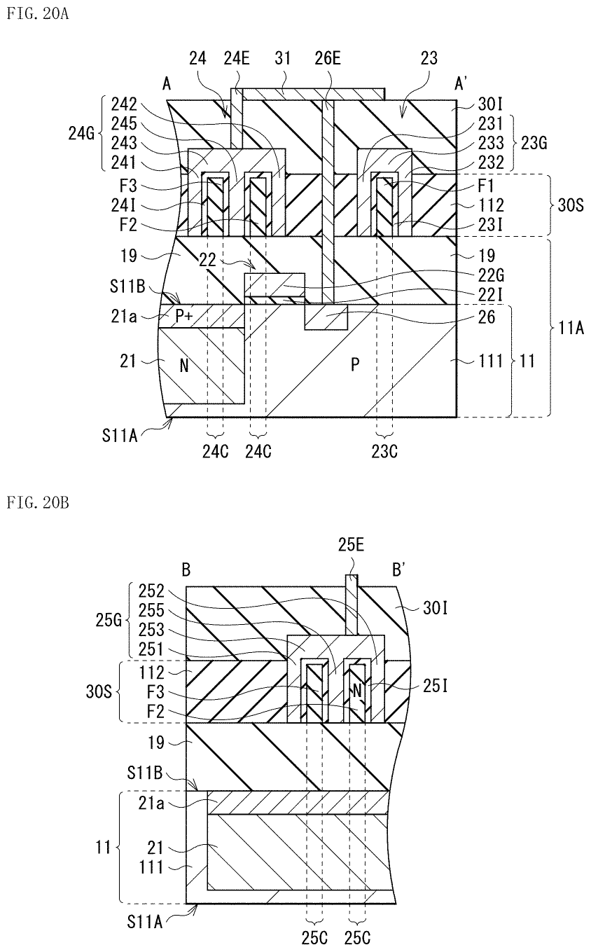

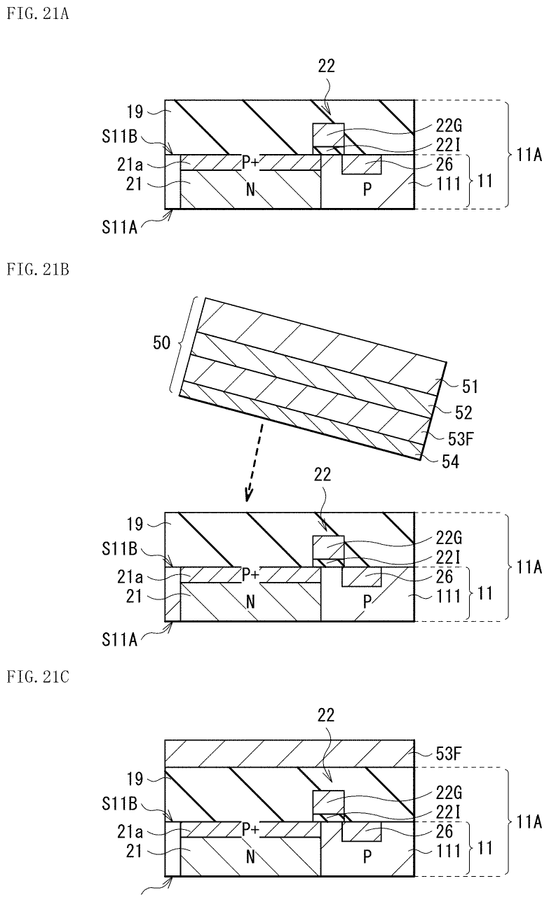

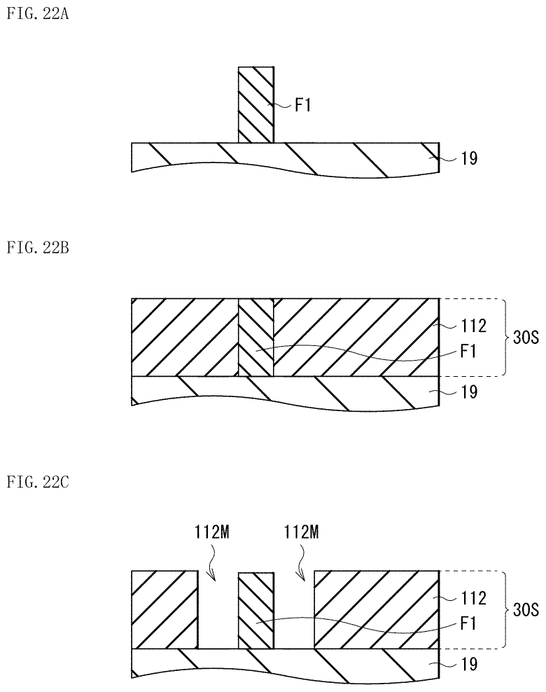

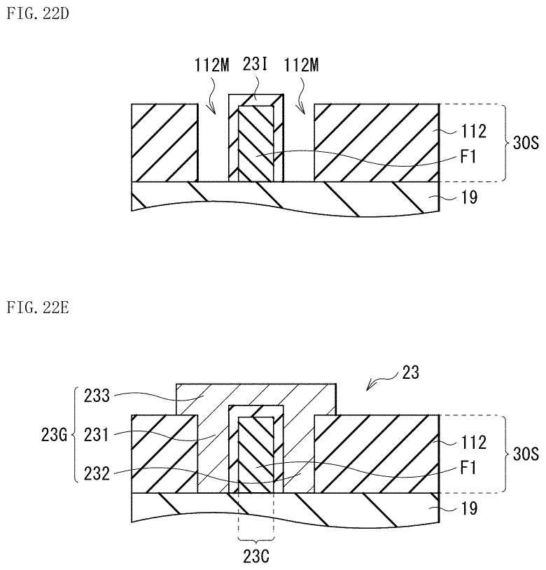

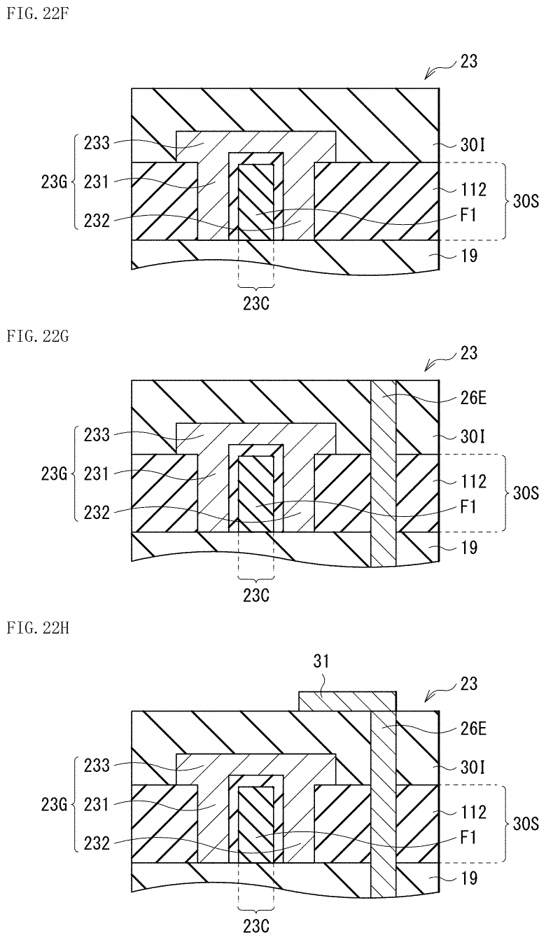

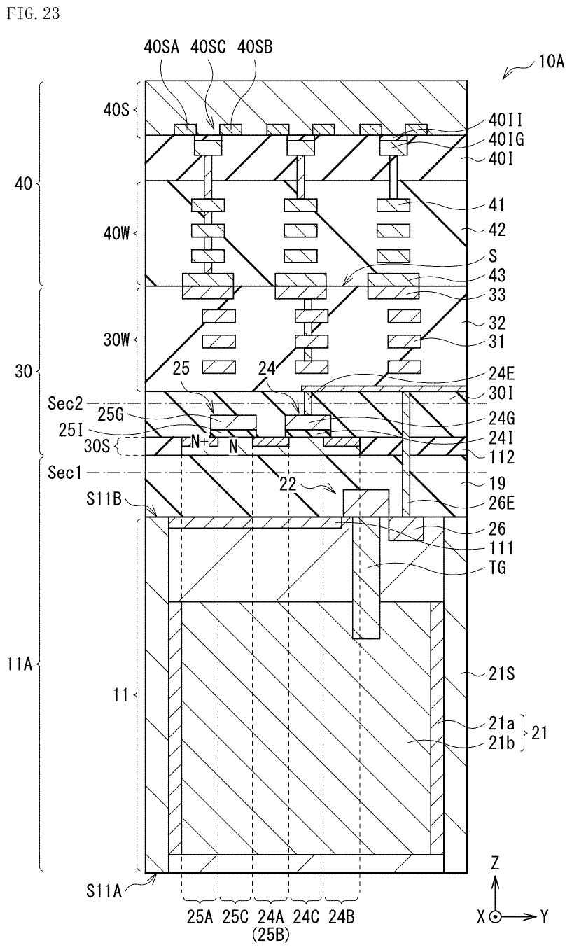

The imaging element 10A including the reset transistor 23, the amplification transistor 24, and the selection transistor 25 as described above may be manufactured, for example, as follows (FIGS. 21A to 22H). Although FIGS. 21A to 22H illustrate the reset transistor 23, the amplification transistor 24 and the selection transistor 25 may be similarly manufactured.

First, as illustrated in FIG. 21A, the first substrate 11A is formed. The first substrate 11A is formed, for example, as follows.

First, the semiconductor substrate 11 is prepared in which a p-type impurity is diffused at an impurity concentration of, for example, about 1×10¹⁶ cm′ to 1×10¹⁸ cm′. The semiconductor substrate 11 having a lower p-type impurity concentration may be used, or alternatively, the semiconductor substrate 11 into which an n-type impurity is diffused may be used. Next, thermal oxidation is performed to form a silicon oxide film having a thickness of about 3 nm to 10 nm, on the surface S11B of the semiconductor substrate 11. Subsequently, on this silicon oxide film, for example, a polysilicon film is formed. Thereafter, the polysilicon film and the silicon oxide film are formed into predetermined shapes by lithography and etching. Thus, the gate electrode 22G and the gate insulating film 221 of the transfer transistor 22 are formed.

After forming the gate electrode 22G and the gate insulating film 221, the photodiode 21 is formed inside the semiconductor substrate 11. The photodiode 21 is formed by, for example, the p-type impurity region 21a having the size in the depth direction of about 30 nm to 200 nm, and the n-type impurity region 21b having the size in the depth direction of about 1 μm to 5 μm. For example, the impurity concentration of the p-type impurity region 21a is about 1×10¹⁸ cm⁻³×1×10¹⁹ cm⁻³, and the impurity concentration of the n-type impurity region 21b is about 1×10¹⁵ cm⁻³×1×10¹⁸ cm⁻³.

After forming the photodiode 21, the FD section 26 is formed inside the semiconductor substrate 11. The FD section 26 is formed of, for example, an n-type impurity diffusion region. The concentration of this FD section 26 is, for example, about 1×10¹⁹ cm⁻³×1×10²⁰ cm⁻³. After the FD section 26 is formed, for example, oxidation annealing is performed at about 1000° C. to 1100° C. for 1 second to 10 seconds. Thereafter, on the semiconductor substrate 11, an insulating film such as silicon oxide is formed to cover the gate electrode 22G and the gate insulating film 221 of the transfer transistor 22. This insulating film is subjected to planarization treatment such as CMP (Chemical Mechanical Polishing) to form the interlayer insulating film 19. Thus, the first substrate 11A is formed.

After forming the first substrate 11A, as illustrated in FIG. 21B, the SOI substrate 50 is bonded to the first substrate 11A. The SOI substrate 50 includes, for example, a first oxide film 52, a semiconductor layer 53F, and a second oxide film 54 on a substrate 51 in this order. The substrate 51 includes, for example, a silicon (Si) substrate. The first oxide film 52 and the second oxide film 54 each include, for example, a silicon oxide (SiO) film. The semiconductor layer 53F includes, for example, a silicon layer in which an n-type impurity is diffused. A concentration of the n-type impurity of this semiconductor layer 53F is, for example, about 1×10¹⁷ cm⁻³×1×10¹⁹ cm⁻³. A thickness of the semiconductor layer 53F is about 200 nm to 1000 nm. The SOI substrate 50 is bonded to the first substrate 11A to allow the second oxide film 54 and the interlayer insulating film 19 to be in contact with each other. Bonding surfaces may be subjected to plasma treatment in advance to increase bonding strength. The concentration of the n-type impurity of the semiconductor layer 53F may be made lower, or alternatively, a p-type impurity may be diffused into the semiconductor layer 53F. An n-type impurity is implanted into the semiconductor layer 53F in a later process. Moreover, instead of the SOI substrate 50, a bulk silicon substrate may be bonded.

After the SOI substrate 50 is bonded to the first substrate 11A, as illustrated in FIG. 21C, the substrate 51 and the first oxide film 52 of the SOI substrate 50 are removed. The removal of the substrate 51 and the first oxide film 52 is carried out with the use of, for example, CMP, etc. In the case where the bulk silicon substrate, instead of the SOI substrate 50, is bonded to the first substrate 11A, the silicon substrate is scraped by, for example, CMP, etc., to adjust to a desired thickness.

After removing the substrate 51 and the first oxide film 52, as illustrated in FIG. 22A, the semiconductor layer 53F is formed into a desired shape using lithography and etching, to form the fin F1 (and F2 and F3). It is to be noted that in FIGS. 22A to 22H, only layers above the interlayer insulating film 19 are illustrated.

After the fin F1 is formed, as illustrated in FIG. 22B, the element isolation region 112 is formed around the fin F1. The element isolation region 112 is formed, for example, as follows. First, an insulating film such as silicon oxide is formed on the interlayer insulating film 19, to cover the fin F1. Thereafter, this insulating film is subjected to planarization treatment such as CMP, to form the element isolation region 112. Thus, the semiconductor layer 30S including the fin F1 (and the fins F2 and F3) and the element isolation region 112 is formed.

After the element isolation region 112 is formed, as illustrated in FIG. 22C, a groove 112M is formed on both sides of the fin F1. The groove 112M penetrates the semiconductor layer 30S and reaches the interlayer insulating film 19. The groove 112M is provided for formation of the pair of the side faces 231 and 232 (and the side faces 241, 242, 251, and 252) of the gate electrode 23G (and the gate electrodes 24G and 25G). The groove 112M is formed with the use of, for example, etching.

After forming the groove 112M in the semiconductor layer 30S, as illustrated in FIG. 22D, the gate insulating film 231 (and the gate insulating films 241 and 251) is formed around the fin F1 (and the fins F2, F3). The gate insulating film 231 is, for example, a silicon oxide (SiO) film formed by thermally oxidizing the fin F1, and has a thickness of about 3 nm to 10 nm. The gate insulating film 231 may be formed by a film forming process.

After forming the gate insulating film 231, as illustrated in FIG. 22E, the gate electrode 23G (and the gate electrodes 24G and 25G) is formed. The gate electrode 23G is formed, for example, as follows. First, for example, p-type polysilicon is formed on the element isolation region 112, to fill the groove 112M. Next, this polysilicon film is subjected to planarization treatment such as CMP. Thereafter, the polysilicon film is formed into a predetermined shape using photolithography and etching. Thus, the gate electrode 23G is formed. After forming the gate electrode 23G, the source-drain regions 23A and 23B (and the source-drain regions 24A and 24B) are formed at a position adjacent to the channel region 23C (and the channel regions 24C and 25C). The source-drain regions 23A and 23B are formed by implanting an n-type impurity into the fin F1 (and the fins F2 and F3). Thereafter, activation annealing is performed, for example, at about 1000° C. to 1100° C. for 1 second to 10 seconds.

Subsequently, as illustrated in FIG. 22F, the interlayer insulating film 301 is formed on the semiconductor layer 30S. The interlayer insulating film 301 is formed, by forming an insulating film to cover the gate electrode 23G, and thereafter, subjecting the insulating film to planarization treatment such as CMP.

After forming the interlayer insulating film 301, as illustrated in FIG. 22G, the electrode 26E (and the electrodes 23E, 24E, and 25E) is formed. The electrode 26E is formed, for example, as follows. First, the connection hole reaching the FD section 26 is formed by, for example, etching. Next, the connection hole is filled with a conductive material such as tungsten (W). Thus, the electrode 26E is formed.

After forming the electrode 26E, as illustrated in FIG. 22H, the wiring 31 is formed on the interlayer insulating film 301. The wiring 31 is formed with the use of, for example, copper (Cu), etc.

Then, the multilayer wiring layer 30W including the other wirings 31, the interlayer insulating film 32, and the contact electrode 33 is formed. Thus, the second substrate 30 is formed. Thereafter, the second substrate 30 is bonded to the third substrate 40 by, for example, Cu—Cu bonding. In this way, the imaging element 10A illustrated in FIGS. 19, 20A, and 20B is completed.

In the imaging element 10A of the present modification example as well, as with the description in the forgoing second embodiment, the amplification transistor 24 includes the channel region 24C of the same electrical conductivity type (n-type) as the electrical conductivity type of the source-drain regions 24A and 24B. Hence, it is possible to reduce the noise due to the carriers trapped at the interface on the side of the channel region 24C on which the gate electrode 24G is disposed. Moreover, the reset transistor 23 and the selection transistor 25 include the channel regions 23C and 25C of the same electrical conductivity type (n-type) as the electrical conductivity type of the source-drain regions 23A, 23B, 25A, and 25B. Hence, it is possible to reduce the noise due to the carriers trapped at the interface on the side of the channel regions 23C and 25C on which the gate electrodes 23G and 25G are disposed.

In the present modification example, the reset transistor 23, the amplification transistor 24, and the selection transistor 25 having the Fin FET structure are described. However, the reset transistor 23, the amplification transistor 24, and the selection transistor 25 may have the GAA structure, as with the description in the forgoing modification example 2 (FIG. 9).

### Modification 5

FIG. 23 illustrates a schematic cross-sectional configuration of a main portion of the imaging element 10A (FIG. 18) according to a modification example (modification example 5) of the forgoing second embodiment. In the imaging element 10A of this modification example 5, the photodiode 21 is provided at a position deeper than the surface S11B (on side on which the surface S11A is disposed), and the transfer transistor 22 includes a vertical transistor (transfer gate TG). Otherwise, the imaging element 10A of the modification example 5 has the similar configuration to the imaging element 10A of the forgoing second embodiment, and has the similar workings and effects as well.

The gate (transfer gate TG) of the transfer transistor 22 extends from the front surface of the semiconductor substrate 11, penetrating the p-type well region 111, to a depth reaching the photodiode 21.

The first substrate 11A includes a pixel separating section 21S that separates each pixel P. The pixel separating section 21S is formed to extend in a normal direction to the semiconductor substrate 11 (direction perpendicular to the surface S11B of the semiconductor substrate 11). The pixel separating section 21S is provided between the two pixels P adjacent to each other. The pixel separating section 21S electrically separates the pixels P adjacent to each other. The pixel separating section 21S includes, for example, silicon oxide. The pixel separating section 21S penetrates, for example, the semiconductor substrate 11. The p-type impurity region 21a and the n-type impurity region 21b are provided on side of the pixel separating section 21S on which a side face of the pixel separating section 21S is disposed.

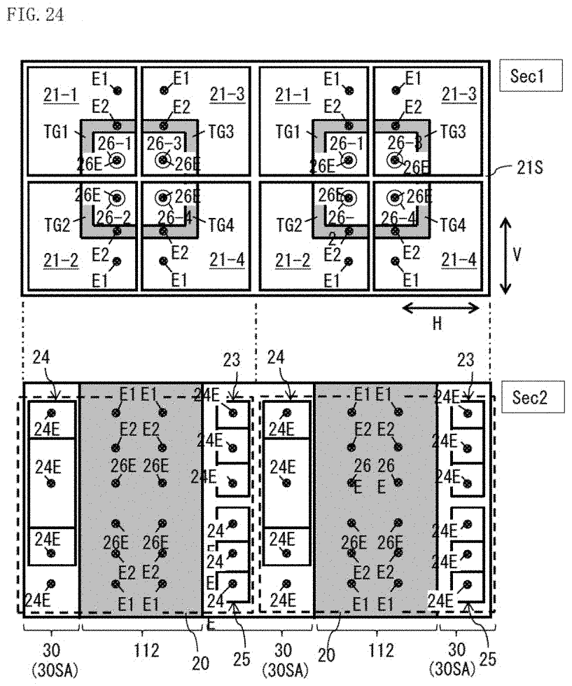

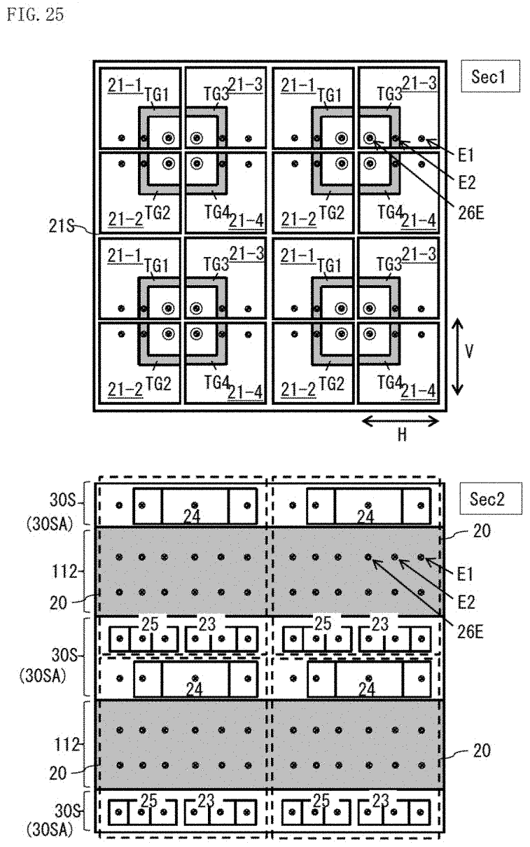

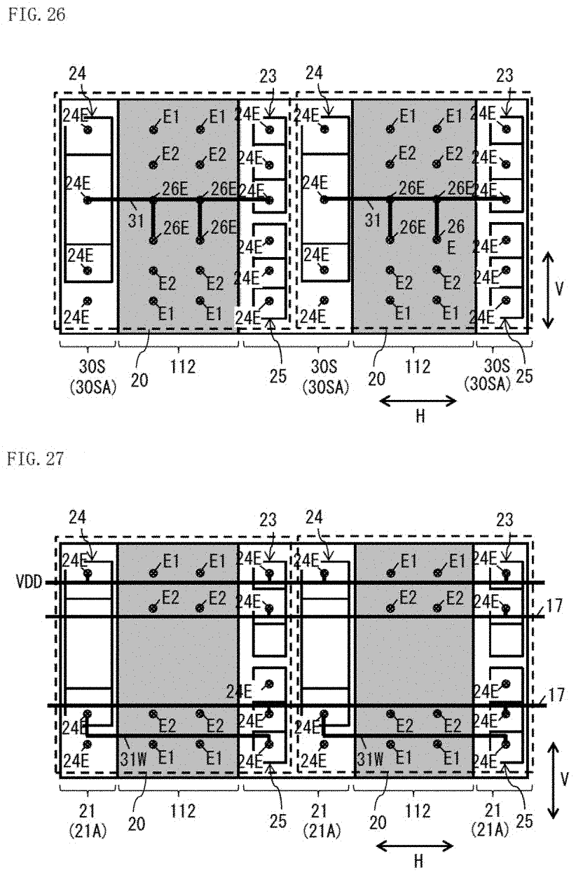

As illustrated in FIG. 23, the first substrate 11A and the second substrate 30 are electrically coupled to each other by the electrode 26E. Furthermore, the first substrate 11A and the second substrate 30 are coupled by the electrodes E1 and E2 penetrating the interlayer insulating films 19 and 301 (see FIGS. 24 and 25 to be described later). In the imaging element 10A, for example, the electrodes E1 and E2 are provided for each pixel P. Moreover, as illustrated in FIG. 23, the second substrate 30 and the third substrate 40 are electrically coupled to each other by bonding of the contact electrodes 33 and 43. Here, a width of the electrode 26E is narrower than a width of a bonding spot of the contact electrodes 33 and 43. That is, cross-sectional area of the electrode 26E is smaller than cross-sectional area of the bonding spot of the contact electrodes 33 and 43. Accordingly, the electrode 26E hardly inhibits miniaturization of area per pixel in the first substrate 11A. Moreover, the readout circuit 20 is formed on the second substrate 30, and the logic circuit LC is formed on the third substrate 40. This makes it possible to form the structure that electrically couples the second substrate 30 and the third substrate 40 to each other, with a layout having more enhanced freedom regarding the number of contacts for arrangement and coupling, as compared to the structure that electrically couples the first substrate 11A and the second substrate 30 to each other. Hence, it is possible to use the bonding of the contact electrodes 33 and 43, as the structure that electrically couples the second substrate 30 and the third substrate 40 to each other.

FIGS. 24 and 25 each illustrate an example of a cross-sectional configuration in the horizontal direction of the imaging element 10A. An upper diagram of each of FIGS. 24 and 25 illustrates an example of a cross-sectional configuration at a cross section Sec1 of FIG. 23, and a lower diagram of each of FIGS. 24 and 25 illustrates an example of a cross-sectional configuration at a cross section Sec2 of FIG. 23. FIG. 24 exemplifies a configuration in which two groups of the four pixels P in a 2×2 arrangement are disposed side by side in a second direction H, and FIG. 25 exemplifies a configuration in which four groups of the four pixels P in the 2×2 arrangement are disposed side by side in a first direction V and the second direction H. It should be noted that, in the upper cross-sectional views of FIGS. 24 and 25, a diagram illustrating an example of a front surface configuration of the semiconductor substrate 11 is superimposed on the diagram illustrating the example of the cross-sectional configuration at the cross section Sec1 of FIG. 23, and the interlayer insulating film 19 is omitted. In addition, in the lower cross-sectional views of FIGS. 24 and 25, a diagram illustrating an example of a front surface configuration of the semiconductor layer 30S is superimposed on the diagram illustrating the example of the cross-sectional configuration at the cross section Sec2 of FIG. 23.

As illustrated in FIGS. 24 and 25, the plurality of the electrodes 26E, the plurality of the electrodes E2, and the plurality of the electrodes E1 are disposed side by side in a band-like fashion in the first direction V (an upward-downward direction in FIG. 10 or a rightward-leftward direction in FIG. 11) in a plane of the first substrate 11A. It should be noted that FIGS. 24 and 25 exemplify a case where the plurality of the electrodes 26E, the plurality of the electrodes E2, and the plurality of the electrodes E1 are disposed side by side in two columns in the first direction V. The first direction V is parallel to one arrangement direction (for example, a column direction) of two arrangement directions (for example, a row direction and the column direction) of the plurality of the pixels P arranged in a matrix. In the four pixels P sharing the readout circuit 20, the four FD sections 26 are disposed close to each other, with the pixel separating section 21S in between, for example. In the four pixels P sharing the readout circuit 20, the four transfer gates TG are disposed to surround the four FD sections 26. For example, the four transfer gates TG form an annular shape.

The element isolation regions 112 includes a plurality of blocks extending in the first direction V. The semiconductor layer 30S includes a plurality of island-shaped blocks 30SA that extends in the first direction V and is disposed side by side in the second direction H orthogonal to the first direction V with the element isolation region 112 interposed therebetween. Each of the blocks 30SA includes, for example, a plurality of groups of the reset transistor 23, the amplification transistor 24, and the selection transistor 25. The single readout circuit 20 shared by the four pixels P includes, for example, the reset transistor 23, the amplification transistor 24, and the selection transistor 25 in a region opposed to the four pixels P. The single readout circuit 20 shared by the four pixels P includes, for example, the amplification transistor 24 in the block 30SA on the left of the element isolation region 112, and the reset transistor 23 and the selection transistor 25 in the block 30SA on the right of the element isolation region 112.

FIGS. 26, 27, 28, and 29 each illustrate an example of a wiring layout in a horizontal plane of the imaging element 10A. FIGS. 26 to 29 each exemplify a case where the single readout circuit 20 shared by the four pixels P is provided in a region opposed to the four pixels P. Wiring lines described in FIGS. 26 to 29 are provided, for example, in different layers from one another in the multilayer wiring layer 30W.

The four electrodes 26E adjacent to one another are electrically coupled to the wiring 31, for example, as illustrated in FIG. 26. The four electrodes 26E adjacent to one another are further electrically coupled to the gate of the amplification transistor 24 included in the block 30SA on the left of the element isolation region 112, and the gate of the reset transistor 23 included in the block 30SA on the right of the element isolation region 112, through the wiring 31 and the electrode 24E, for example, as illustrated in FIG. 26.

The power supply line VDD is disposed at a position opposed to each of the readout circuits 20 disposed side by side in the second direction H, for example, as illustrated in FIG. 27. The power supply line VDD is electrically coupled, through the electrode 24E, to the drain of the amplification transistor 24 and the drain of the reset transistor 23 in each of the readout circuits 20 disposed side by side in the second direction H, for example, as illustrated in FIG. 27. The two pixel drive lines 17 are each disposed at a position opposed to each of the readout circuits 20 disposed side by side in the second direction H, for example, as illustrated in FIG. 27. One of the pixel drive lines 17 (second control line) is a wiring RSTG electrically coupled to the gate of the reset transistor 23 of each of the readout circuits 20 disposed side by side in the second direction H, for example, as illustrated in FIG. 27. The other of the pixel drive lines 17 (third control line) is a wiring SELG electrically coupled to the gate of the selection transistor 25 of each of the readout circuits 20 disposed side by side in the second direction H, for example, as illustrated in FIG. 27. In each of the readout circuits 20, the source of the amplification transistor 24 and the drain of the selection transistor 25 are electrically coupled to each other through a wiring 31W, for example, as illustrated in FIG. 27.

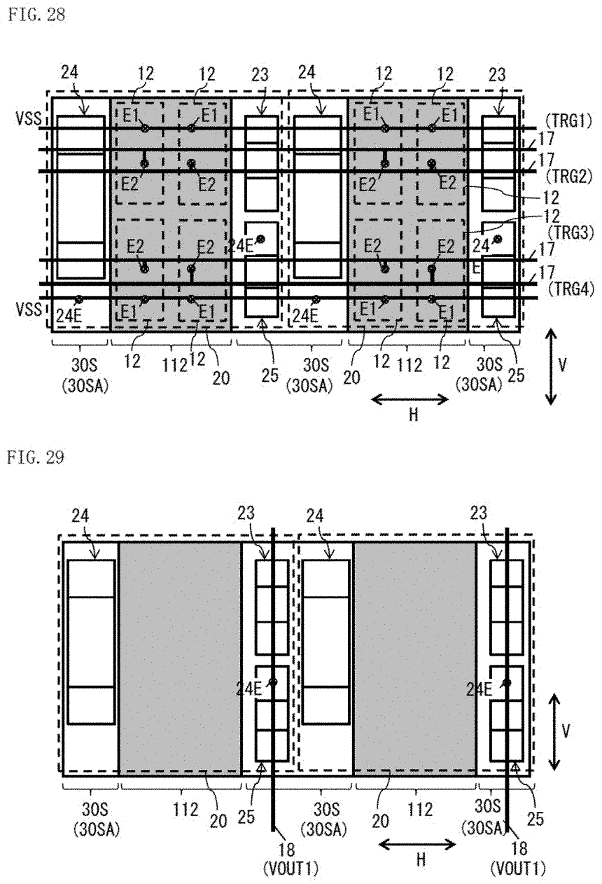

Two power supply lines VSS are each disposed at a position opposed to each of the readout circuits 20 disposed side by side in the second direction H, for example, as illustrated in FIG. 28. Each of the power supply lines VSS is electrically coupled to the plurality of the electrodes E1 at positions opposed to the respective pixels P disposed side by side in the second direction H, for example, as illustrated in FIG. 28. The four pixel drive lines 17 are each disposed at a position opposed to each of the readout circuits 20 disposed side by side in the second direction H, for example, as illustrated in FIG. 28. Each of the four pixel drive lines 17 is a wiring TRG electrically coupled to the electrode E2 of one pixel P of the four pixels P corresponding to each of the readout circuits 20 disposed side by side in the second direction H, for example, as illustrated in FIG. 28. That is, the four pixel drive lines 17 (first control lines) are electrically coupled to the gates (the transfer gates TG) of the transfer transistors 22 of the respective pixels P disposed side by side in the second direction H. In FIG. 28, identifiers (1, 2, 3, and 4) are given to ends of the respective wirings TRG to distinguish the respective wirings TRG.

The vertical signal line 18 is disposed at a position opposed to each of the readout circuits 20 disposed side by side in the first direction V, for example, as illustrated in FIG. 29. The vertical signal line 18 (output line) is electrically coupled to the output terminal (the source of the amplification transistor 24) of each of the readout circuits 20 disposed side by side in the first direction V, for example, as illustrated in FIG. 29.

In the present modification example, the pixel P and the readout circuit 20 are formed on different substrates from each other (the first substrate 11A and the second substrate 30). Thus, as compared with a case where the pixel P and the readout circuit 20 are formed on the same substrate, it is possible to enlarge the area of the pixel P and the readout circuit 20. As a result, it is possible to enhance the photoelectric conversion efficiency and reduce the transistor noise. Moreover, the first substrate 11A including the pixel P and the second substrate 30 including the readout circuit 20 are electrically coupled to each other by the electrode 26E provided in the interlayer insulating films 19 and 301. This leads to further downsizing of the chip size, as compared to a case where the first substrate 11A and the second substrate 30 are electrically coupled to each other by bonding of pad electrodes or by a through-wiring penetrating a semiconductor substrate (e.g., TSV (Thorough Si Via)). Moreover, further miniaturization of the area per pixel allows higher resolution. Furthermore, in a case of the same chip size as before, it is possible to enlarge a formation region of the pixels P. Moreover, in the present modification example, the readout circuit 20 and the logic circuit LC are formed on different substrates from each other (the second substrate 30 and the third substrate 40). This makes it possible to enlarge the area of the readout circuit 20 and the logic circuit LC, as compared to a case where the readout circuit 20 and the logic circuit LC are formed on the same substrate. In addition, the area of the readout circuit 20 and the logic circuit LC is not limited by the pixel separating section 21S. Hence, it is possible to enhance noise characteristics. Moreover, in the present modification example, the second substrate 30 and the third substrate 40 are electrically coupled to each other, by the bonding of the contact electrodes 33 and 43. Here, the readout circuit 20 is formed on the second substrate 30, and the logic circuit LC is formed on the third substrate 40. This makes it possible to form the structure that electrically couples the second substrate 30 and the third substrate 40 to each other, with a layout having more enhanced freedom regarding the number of contacts for arrangement and coupling, as compared to the structure that electrically couples the first substrate 11A and the second substrate 30 to each other. Hence, it is possible to use the bonding of the contact electrodes 33 and 43, for the electrical coupling between the second substrate 30 and the third substrate 40. As described, in the present modification example, the electrical coupling between the substrates is made in accordance with the degree of integration of the substrate. This suppresses the structure that electrically couples the substrates to one another from causing an increase in the chip size, or from inhibiting the miniaturization of the area per pixel. As a result, it is possible to provide the imaging element 10A having the three-layer structure that hardly inhibits the miniaturization of the area per pixel, with the same chip size as before.

Moreover, in the present modification example, the pixel P including the photodiode 21, the transfer transistor 22, and the FD section 26 is formed on the first substrate 11A, and the readout circuit 20 including the reset transistor 23, the amplification transistor 24, and the selection transistor 25 is formed on the second substrate 30. This makes it possible to enlarge the area of the pixel P and the readout circuit 20, as compared to a case where the pixel P and the readout circuit 20 are formed on the same substrate. As a result, the use of the bonding of the contact electrodes 33 and 43 for the electrical coupling between the second substrate 30 and the third substrate 40 hardly causes the increase in the chip size, or hardly inhibits the miniaturization of the area per pixel. As a result, it is possible to provide the imaging element 10A having the three-layer structure that hardly inhibits the miniaturization of the area per pixel, with the same chip size as before. Specifically, the number of the transistors to be provided on the first substrate 11A is reduced, making it possible to enlarge the area of, in particular, the photodiode 21 of the pixel P. Hence, it is possible to increase the amount of saturation of signal electric charges in the photoelectric conversion, leading to enhancement in the photoelectric conversion efficiency. In the second substrate 30, it is possible to ensure the degree of freedom in the layout of each transistor in the readout circuit 20. Moreover, it is possible to enlarge the area of each transistor. Accordingly, in particular, enlarging the area of the amplification transistor 24 makes it possible to reduce the noise affecting the pixel signal. The use of the bonding of the contact electrodes 33 and 43 for the electrical coupling between the second substrate 30 and the third substrate 40 hardly causes the increase in the chip size, or hardly inhibits the miniaturization of the area per pixel. As a result, it is possible to provide the imaging element 10A having the three-layer structure that hardly inhibits the miniaturization of the area per pixel, with the same chip size as before.

Moreover, in the present modification example, the second substrate 30 is bonded to the first substrate 11A, with a rear surface of the semiconductor layer 30S directed toward the front-surface side of the semiconductor substrate 11. The third substrate 40 is bonded to the second substrate 30, with the front-surface side of the semiconductor layer 40S directed toward the front-surface side of the semiconductor layer 30S. Thus, using the electrode 26E for the electrical coupling between the first substrate 11A and the second substrate 30, and using the bonding of the contact electrodes 33 and 43 for the electrical coupling between the second substrate 30 and the third substrate 40 make it possible to provide the imaging element 10A having the three-layer structure that hardly inhibits the miniaturization of the area per pixel, with the same chip size as before.

Furthermore, in the present modification example, the cross-sectional area of the electrode 26E is smaller than the cross-sectional area of the bonding spot between the contact electrodes 33 and 43. Hence, it is possible to provide the imaging element 10A having the three-layer structure that hardly inhibits the miniaturization of the area per pixel, with the same chip size as before.

Further, in the logic circuit LC of the present modification example, on the front surface of the impurity diffusion region in contact with the source electrode and the drain electrode, the low-resistance region is formed that includes silicide such as CoSi₂ or NiSi. The silicide is formed with the use of the salicide (Self Aligned Silicide) process. The low resistance region including silicide includes a compound of a material of the semiconductor substrate and a metal. Here, the logic circuit LC is provided on the third substrate 40. Therefore, it is possible to form the logic circuit LC in a separate process from the process of forming the pixel P and the readout circuit 20. As a result, in forming the pixel P and the readout circuit 20, it is possible to use a high-temperature process such as thermal oxidation. Moreover, for the logic circuit LC, silicide, a material having low heat resistance may be also used. Thus, in the case where the low resistance region including silicide is provided on the front surface of the impurity diffusion region in contact with the source electrode and the drain electrode of the logic circuit LC, it is possible to reduce the contact resistance. As a result, it is possible to improve a calculation speed in the logic circuit LC.

Furthermore, in the present modification example, on the first substrate 11A, the pixel separating section 21S that separates each pixel P is provided. However, in the present modification example, the pixel P including the photodiode 21, the transfer transistor 22, and the FD section 26 is formed on the first substrate 11A. The readout circuit 20 including the reset transistor 23, the amplification transistor 24, and the selection transistor 25 is formed on the second substrate 30. Thus, even in a case where the area surrounded by the pixel separating section 21S is reduced because of the miniaturization of the area per pixel, it is possible to enlarge the area of the pixel P and the readout circuit 20. As a result, the use of the pixel separating section 21S hardly causes the increase in the chip size, or hardly inhibits the miniaturization of the area per pixel. Hence, it is possible to provide the imaging element 10A having the three-layer structure that hardly inhibits the miniaturization of the area per pixel, with the same chip size as before.

Moreover, in the present modification example, the pixel separating section 21S penetrates the semiconductor substrate 11. Thus, even in a case where the distance between the pixels P becomes small because of the miniaturization of the area per pixel, it is possible to suppress signal crosstalk between the adjacent pixels P. This leads to suppression of lowered resolution of reproduced images or deterioration in image quality caused by color mixture.

Furthermore, in the modification example, a stacked body including the first substrate 11A and the second substrate 30 includes the three electrodes 26E, E1, and E2 for each pixel P. The electrode 26E is electrically coupled to the gate (transfer gate TG) of the transfer transistor 22. The electrode E1 is electrically coupled to the p-type well region 111 of the semiconductor substrate 11. The electrode E2 is electrically coupled to the FD section 26. That is, the number of the electrodes 26E, E1, and E2 is greater than the number of the pixels P included in the first substrate 11A. However, in the present modification example, the electrode 26E having the small cross-sectional area is used for the electrical coupling between the first substrate 11A and the second substrate 30. This leads to further miniaturization of the chip size, and also leads to further miniaturization of the area per pixel in the first substrate 11A. As a result, it is possible to provide the imaging element 10A having the three-layer structure that hardly inhibits the miniaturization of the area per pixel, with the same chip size as before.

### Modification Example 6

FIG. 30 illustrates a modification example of the cross-sectional configuration in the vertical direction of the imaging element 10A according to a modification example (modification example 6) of the second embodiment described above. In the present modification example, the electrical coupling between the second substrate 30 and the third substrate 40 is made in a region opposed to a peripheral region 12B of the first substrate 11A. The peripheral region 12B corresponds to a frame region of the first substrate 11A and is provided on the periphery of the pixel array unit 12. In the present modification example, the second substrate 30 includes a plurality of the contact electrodes 33 in a region opposed to the peripheral region 12B, and the third substrate 40 includes a plurality of the contact electrodes 44 in a region opposed to the peripheral region 12B. The second substrate 30 and the third substrate 40 are electrically coupled to each other by the bonding of the contact electrodes 33 and 43 provided in the regions opposed to the peripheral region 12B.

As described above, in the present modification example, the second substrate 30 and the third substrate 40 are electrically coupled to each other by the bonding of the contact electrodes 33 and 43 provided in the regions opposed to the peripheral region 12B. This makes it possible to reduce a possibility of inhibition of the miniaturization of area per pixel, as compared with a case where the contact electrodes 33 and 43 are bonded to each other in regions opposed to the pixel array unit 12. Accordingly, it is possible to provide the imaging element 10A having the three-layer structure that hardly inhibits the miniaturization of the area per pixel, with the same chip size as before.

### Modification Example 7

FIGS. 31 and 32 each illustrate a modification example of the cross-sectional configuration in the horizontal direction of the imaging element 10A according to the second embodiment described above. An upper diagram of each of FIGS. 31 and 32 illustrates a modification example of the cross-sectional configuration at the cross section Sec1 of FIG. 23, and a lower diagram of FIG. 31 illustrates a modification example of the cross-sectional configuration at the cross section Sec2 of FIG. 23. It should be noted that, in the upper cross-sectional views of FIGS. 31 and 32, a diagram illustrating a modification example of the front surface configuration of the semiconductor substrate 11 in FIG. 23 is superimposed on the diagram illustrating the modification example of the cross-sectional configuration at the cross section Sec1 of FIG. 23, and the interlayer insulating layer 19 is omitted. In addition, in the lower cross-sectional views of FIGS. 31 and 32, a diagram illustrating a modification example of the front surface configuration of the semiconductor layer 30S is superimposed on the diagram illustrating the modification example of the cross-sectional configuration at the cross section Sec2 of FIG. 23.

As illustrated in FIGS. 31 and 32, the plurality of the electrodes 26E, the plurality of the electrodes E2, and the plurality of the electrodes E1 (a plurality of dots disposed in rows and columns in the diagrams) are disposed side by side in a band-like fashion in the first direction V (rightward-leftward direction in FIGS. 23 and 24) in the plane of the first substrate 11A. It should be noted that FIGS. 31 and 32 exemplify a case where the plurality of the electrodes 26E, the plurality of the electrodes E2, and the plurality of the electrodes E1 are disposed side by side in two columns in the first direction V. In the four pixels P sharing the readout circuit 20, the four FD sections 26 are disposed close to each other, for example, with the pixel separating section 21S interposed therebetween. In the four pixels P sharing the readout circuit 20, the four transfer gates TG (TG1, TG2, TG3, and TG4) are disposed to surround the four FD sections 26, and the four transfer gates TG form an annular shape, for example.

The element isolation region 112 includes the plurality of the blocks extending in the first direction V. The semiconductor layer 30S includes the plurality of the island-shaped blocks 30SA that extends in the first direction V and is disposed side by side in the second direction H orthogonal to the first direction V with the element isolation region 112 interposed therebetween. Each of the blocks 30SA includes, for example, the reset transistor 23, the amplification transistor 24, and the selection transistor 25. The single readout circuit 20 shared by the four pixels P is not disposed directly opposed to the four pixels P, but is disposed to be shifted in the second direction H, for example.

In FIG. 31, the single readout circuit 20 shared by the four pixels P includes the reset transistor 23, the amplification transistor 24, and the selection transistor 25 in a region shifted in the second direction H from a region opposed to the four pixels P in the second substrate 30. The single readout circuit 20 shared by the four pixels P includes, for example, the amplification transistor 24, the reset transistor 23, and the selection transistor 25 in the single block 30SA.

In FIG. 32, the single readout circuit 20 shared by the four pixels P includes the reset transistor 23, the amplification transistor 24, the selection transistor 25, and the FD transfer transistor 27 in the region shifted in the second direction H from the region opposed to the four pixels P in the second substrate 30. The single readout circuit 20 shared by the four pixels P includes, for example, the amplification transistor 24, the reset transistor 23, the selection transistor 25, and the FD transfer transistor 27 in the single block 30SA.

In the present modification example, the single readout circuit 20 shared by the four pixels P is not disposed directly opposed to the four pixels P, but is disposed to be shifted in the second direction H from the position directly opposed to the four pixels P, for example. In such a case, it is possible to shorten the wiring 31, or alternatively, it is possible to omit the wiring 31 and form the source of the amplification transistor 24 and the drain of the selection transistor 25 in a common impurity region. As a result, it is possible to reduce the size of the readout circuit 20 or increase a size of any other portion in the readout circuit 20.

### Modification Example 8

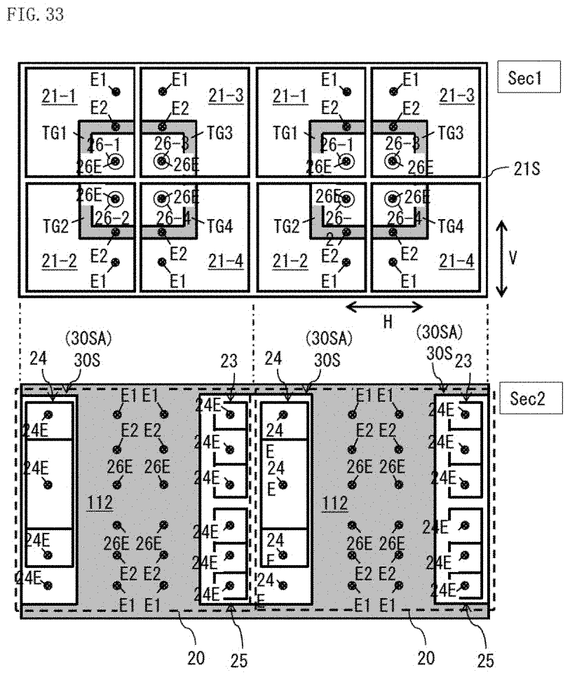

FIG. 33 illustrates a modification example of the cross-sectional configuration in the horizontal direction of the imaging element 10A according to the second embodiment described above. FIG. 33 illustrates a modification example of the cross-sectional configuration in FIG. 24.

In the present modification example, the semiconductor layer 30S includes the plurality of the island-shaped blocks 30SA disposed side by side in the first direction V and the second direction H with the element isolation regions 112 interposed therebetween. Each of the blocks 30SA includes, for example, one group of the reset transistor 23, the amplification transistor 24, and the selection transistor 25. In such a case, it is possible to suppress crosstalk between the readout circuits 20 adjacent to each other by the element isolation regions 112. This leads to the suppression of the lowered resolution of the reproduced images and the deterioration in image quality caused by color mixture.

### Modification Example 9

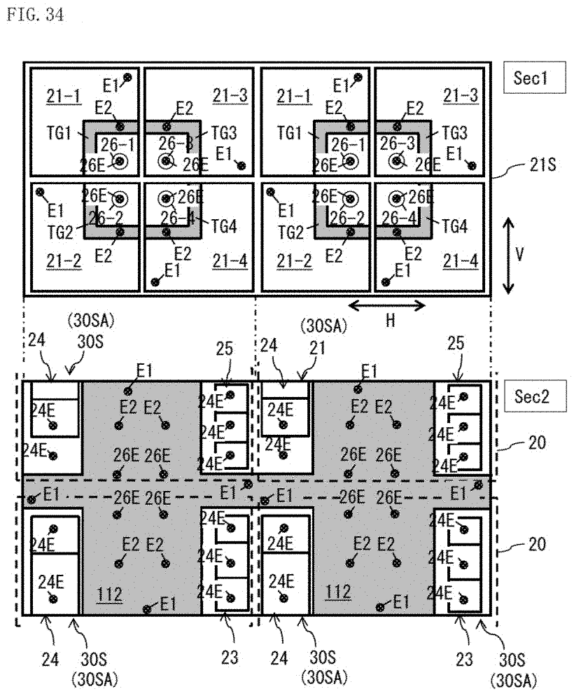

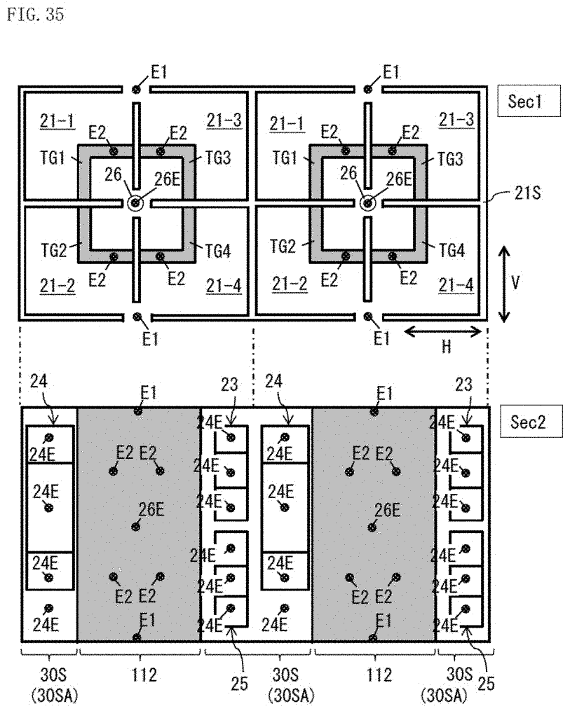

FIG. 34 illustrates a modification example of the cross-sectional configuration in the horizontal direction of the imaging element 10A according to the second embodiment described above. FIG. 34 illustrates a modification example of the cross-sectional configuration in FIG. 33.

In the present modification example, the single readout circuit 20 shared by the four pixels P is not disposed directly opposed to the four pixels P, but is disposed to be shifted in the first direction V. Furthermore, in the present modification example, as with the modification example 8, the semiconductor layer 30S includes the plurality of the island-shaped blocks 30SA disposed side by side in the first direction V and the second direction H with the element isolation regions 112 interposed therebetween. Each of the blocks 30SA includes, for example, one group of the reset transistor 23, the amplification transistor 24, and the selection transistor 25. Furthermore, in the present modification example, the plurality of the electrodes E1 and the plurality of the electrodes 26E are also arranged in the second direction H. Specifically, the plurality of the electrodes E1 is disposed between the four electrodes 26E sharing any one of the readout circuits 20, and the four electrodes 26E sharing another of the readout circuits 20 adjacent in the second direction H to the relevant readout circuit 20. In such a case, it is possible to suppress crosstalk between the readout circuits 20 adjacent to each other by the element isolation region 112 and the electrodes E1. This leads to the suppression of the lowered resolution of the reproduced images and the deterioration in image quality caused by color mixture.

### Modification Example 10

FIG. 35 illustrates an example of the cross-sectional configuration in the horizontal direction of the imaging element 10A according to the second embodiment and the modification examples thereof described above. FIG. 35 illustrates a modification example of the cross-sectional configuration in FIG. 24.

In the present modification example, the first substrate 11A includes the photodiode 21 and the transfer transistor 22 for each pixel P, and the FD section 26 is shared by every four pixels P. Accordingly, in the present modification example, the single electrode 26E is provided for every four pixels P.

In the plurality of the pixels P arranged in a matrix, for the sake of convenience, the four pixels P are referred to as the four pixels PA that correspond to a region obtained by shifting a unit region in the first direction V by the single pixel P. The unit region corresponds to the four pixels P sharing the single FD section 26. At this time, in the present modification example, in the first substrate 11A, the electrode E1 is shared by every four pixels PA. Accordingly, in the present modification example, the single electrode E1 is provided for every four pixels PA.

In the present modification example, the first substrate 11A includes the pixel separating section 21S that separates the photodiodes 21 and the transfer transistors 22 for each pixel P. As viewed from the normal direction to the semiconductor substrate 11, the pixel separating section 21S does not completely surround the pixel P, but has gaps (unformed regions) in the vicinity of the FD section 26 (the electrode 26E) and in the vicinity of the electrode E1. Thus, the gaps allow for sharing of the single electrode 26E by the four pixels P, and sharing of the single electrode E1 by the four pixels P. In the present modification example, the second substrate 30 includes the readout circuit 20 for every four pixels P sharing the FD section 26.

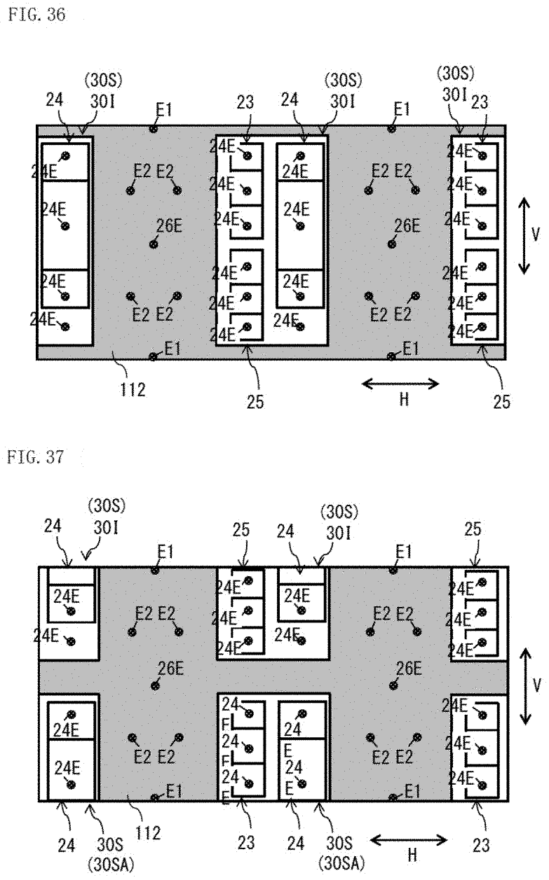

FIG. 36 illustrates an example of the cross-sectional configuration in the horizontal direction of the imaging element 10A according to the present modification example. FIG. 36 illustrates a modification example of the cross-sectional configuration in FIG. 33. In the present modification example, the first substrate 11A includes the photodiode 21 and the transfer transistor 22 for each pixel P, and the FD section 26 is shared by every four pixels P. Furthermore, the first substrate 11A includes the pixel separating section 21S that separates the photodiodes 21 and the transfer transistors 22 for each pixel P.

FIG. 37 illustrates an example of the cross-sectional configuration in the horizontal direction of the imaging element 10A according to the present modification example. FIG. 37 illustrates a modification example of the cross-sectional configuration in FIG. 34. In the present modification example, the first substrate 11A includes the photodiode 21 and the transfer transistor 22 for each pixel P, and the FD section 26 is shared by every four pixels P. Furthermore, the first substrate 11A includes the pixel separating section 21S that separates the photodiodes 21 and the transfer transistors 22 for each pixel P.

### Modification Example 11

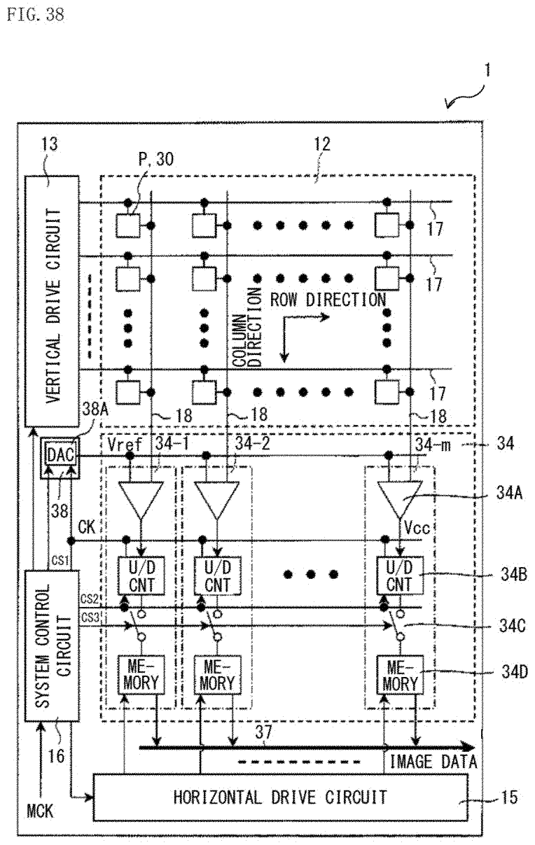

FIG. 38 illustrates an example of a circuit configuration of the imaging element 10A according to the second embodiment and the modification examples thereof described above. The imaging element 10A according to the present modification example is a CMOS image sensor including a column parallel ADC.

As illustrated in FIG. 38, the imaging element 10A according to the present modification example includes the vertical drive circuit 13, the signal processing circuit 14, a reference voltage supply unit 38, the horizontal drive circuit 15, a horizontal output line 37, and the system control circuit 16, in addition to the pixel array unit 12 including the plurality of the pixels P two-dimensionally arranged in rows and columns (a matrix), the plurality of the pixels P each including a photoelectric conversion element.

In this system configuration, the system control circuit 16 generates, for example, a clock signal and a control signal that serve as references of operations of, for example, the vertical drive circuit 13, the signal processing circuit 14, the reference voltage supply unit 38, and the horizontal drive circuit 15, on the basis of a master clock MCK, and supplies the clock signal and the control signal, etc., to the vertical drive circuit 13, the signal processing circuit 14, the reference voltage supply unit 38, and the horizontal drive circuit 15, etc.

In addition, the vertical drive circuit 13 is formed, together with each of the pixels P in the pixel array unit 12, in the first substrate 11A, and is also formed in the second substrate 30 in which the readout circuits 20 are formed. The signal processing circuit 14, the reference voltage supply unit 38, the horizontal drive circuit 15, the horizontal output line 37, and the system control circuit 16 are formed in the third substrate 40.

Although not illustrated here, as the pixels P, for example, it is possible to use those having a configuration including the transfer transistor 22 in addition to the photodiode 21. The transfer transistor 22 transfers, to the FD section 26, electric charges obtained by the photoelectric conversion in the photodiode 21. In addition, although not illustrated here, as the readout circuits 20, for example, it is possible to use those having a three-transistor configuration including the reset transistor 23 that controls the potential of the FD section 26, the amplification transistor 24 that outputs a signal corresponding to the potential of the FD section 26, and the selection transistor 25 for pixel selection.

In the pixel array unit 12, the pixels P are two-dimensionally arranged. With respect to this pixel arrangement of m rows and n columns, the pixel drive lines 17 are wired for respective rows, and the vertical signal lines 18 are wired for respective columns. One end of each of the plurality of the pixel drive lines 17 is coupled to a corresponding one of output terminals corresponding to the respective rows, of the vertical drive circuit 13. The vertical drive circuit 13 includes, for example, a shift register, and performs a control of a row address and row scanning of the pixel array unit 12 through the plurality of the pixel drive lines 17.

The signal processing circuit 14 includes, for example, ADCs (analog-digital conversion circuits) 34-1 to 34-m provided for the respective pixel rows of the pixel array unit 12, i.e., for the respective vertical signal lines 18, and converts analog signals outputted on a column-by-column basis from the respective pixels P in the pixel array unit 12 into digital signals, and outputs the digital signals.

The reference voltage supply unit 38 includes, for example, a DAC (digital-to-analog conversion circuit) 38A as a means of generating a reference voltage Vref of a so-called ramp (RAMP) waveform, of which a level is varied gradiently with time. It should be noted that, as the means of generating the reference voltage Vref of the ramp waveform is not limited to the DAC 38A.

The DAC 38A generates the reference voltage Vref of the ramp waveform on the basis of a clock CK supplied from the system control circuit 16 under control by a control signal CS1 supplied from the system control circuit 16, and supplies the reference voltage Vref to the ADCs 34-1 to 34-m of the signal processing circuit 14.

It should be noted that each of the ADCs 34-1 to 34-m is configured to selectively perform an AD conversion operation corresponding to each of operation modes. The operation modes include a normal frame rate mode in a progressive scanning system in which information of all the pixels P is read out, and a high frame rate mode in which an exposure time of the pixels P is set to 1/N to increase a frame rate by N times, for example, twice the frame rate in the normal frame rate mode. Such switching of the operation modes is executed by a control with control signals CS2 and CS3 supplied from the system control circuit 16. In addition, the system control circuit 16 is provided with instruction information for switching between the respective operation modes, that is, the normal frame rate mode and the high frame rate mode, from an external system controller (not illustrated).

The ADCs 34-1 to 34-m all have the same configuration, and the ADC 34-m is described here as an example. The ADC 34-m has a configuration including a comparator 34A, for example, an up-down counter (which is referred to as “U/DCNT” in the diagram) 34B serving as a counting means, a transfer switch 34C, and a memory device 34D.

The comparator 34A compares a signal voltage Vx of the vertical signal line 18 corresponding to a signal outputted from each of the pixels P in an n-th column of the pixel array unit 12, with the reference voltage Vref of the ramp waveform supplied from the reference voltage supply unit 38. For example, in a case where the reference voltage Vref is larger than the signal voltage Vx, an output Vco is brought to an “H” level. In a case where the reference voltage Vref is equal to or smaller than the signal voltage Vx, the output Vco is brought to an “L” level.

The up-down counter 34B includes an asynchronous counter. Under control by the control signal CS2 supplied from the system control circuit 16, the up-down counter 34B is supplied with the clock CK from the system control circuit 16 simultaneously with the DAC 18A, and carries out down (DOWN)-counting or up (UP)-counting in synchronization with the clock CK, to measure comparison time from a start of comparison operation in the comparator 34A to an end of the comparison operation.

Specifically, in the normal frame rate mode, in a readout operation of a signal from the single pixel P, the down-counting is carried out in a first readout operation, to measure the comparison time in a first readout. The up-counting is carried out in a second readout operation, to measure the comparison time in a second readout.

In contrast, in the high frame rate mode, a counting result of the pixels Pin any row is kept as it is. Subsequently, for the pixels Pin a subsequent row, the down-counting is carried out in the first readout operation from the previous counting result, to measure the comparison time in the first readout. The up-counting is carried out in the second readout operation, to measure the comparison time in the second readout.

In the normal frame rate mode, under control by the control signal CS3 supplied from the system control circuit 16, the transfer switch 34C is turned to an ON (closed) state, at timing of completion of the counting operation for the pixels P in any row by the up-down counter 34B, and transfers the relevant counting result by the up-down counter 34B to the memory device 34D.

In contrast, at a high frame rate of N=2, the transfer switch 34C remains in an OFF (open) state, at timing of completion of the counting operation for the pixels P in any row by the up-down counter 34B. Subsequently, the transfer switch 34C is turned to the ON state, at timing of completion of the counting operation for the pixels P in a subsequent row by the up-down counter 34B, and transfers the counting result of two vertical pixels by the up-down counter 34B to the memory device 34D.

As described above, the analog signals supplied from the respective pixels P in the pixel array unit 12 on the column-by-column basis through the vertical signal lines 18 are converted into the N-bit digital signals by the respective operations by the comparator 34A and the up-down counter 34B in the ADCs 34-1 to 34-m, and the digital signals are stored in the memory device 34D.

The horizontal drive circuit 15 includes, for example, a shift register, and performs a control of column addresses and column scanning of the ADCs 34-1 to 34-m in the signal processing circuit 14. Under control by the horizontal drive circuit 15, the N-bit digital signals A/D converted in the respective ADCs 34-1 to 34-m are sequentially read out to the horizontal output line 37, and are outputted as imaging data through the horizontal output line 37.

It should be noted that a circuit and the like that perform various kinds of signal processing on the imaging data to be outputted through the horizontal output line 37 may be provided in addition to the constituent elements described above. However, the circuit and the like are not illustrated, because the circuit and the like are not directly related to the present disclosure.

In the imaging element 10A including the column parallel ADC that has the above-described configuration according to the present modification example, it is possible to selectively transfer the counting result of the up-down counter 34B to the memory device 34D through the transfer switch 34C. Hence, it is possible to independently control the counting operation by the up-down counter 34B and the readout operation of the counting result by the up-down counter 34B to the horizontal output line 37.

### Modification Example 12

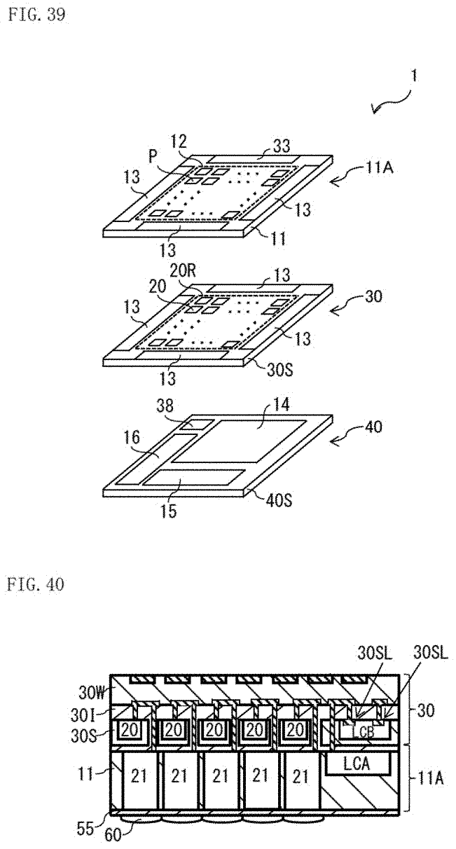

FIG. 39 illustrates an example in which the imaging element in FIG. 38 is configured by stacking three substrates (the first substrate 11A, the second substrate 30, and the third substrate 40). In the present modification example, in the first substrate 11A, the pixel array unit 12 including the plurality of the pixels P is formed in a central portion, and the vertical drive circuit 13 is formed around the pixel array unit 12. In addition, in the second substrate 30, a readout circuit region 20R including the plurality of the readout circuits 20 is formed in a central portion, and the vertical drive circuit 13 is formed around the readout circuit region 20R. In the third substrate 40, the signal processing circuit 14, the horizontal drive circuit 15, the system control circuit 16, the horizontal output line 37, and the reference voltage supply unit 38 are formed. Thus, as with the embodiment and the modification examples thereof described above, the structure of the electrical coupling of the substrates hardly causes the increase in the chip size, and hardly inhibits the miniaturization of the area per pixel. As a result, it is possible to provide the imaging element 10A having the three-layer structure that hardly inhibits the miniaturization of the area per pixel, with the same chip size as before. It should be noted that the vertical drive circuit 13 may be formed only in the first substrate 11A, or may be formed only in the second substrate 30.

### Modification Example 13

FIG. 40 illustrates a modification example of the cross-sectional configuration of the imaging element 10A according to the second embodiment and the modification examples thereof described above. In the second embodiment and the modification examples thereof described above, the imaging element 10A is configured by stacking three substrates (the first substrate 11A, the second substrate 30, and the third substrate 40). However, in the second embodiment and the modification examples thereof described above, the imaging element 10A may be configured by stacking two substrates (the first substrate 11A and the second substrate 30). At this time, for example, as illustrated in FIG. 40, the logic circuit LC is separated to be formed in the first substrate 11A and the second substrate 30. Here, a circuit LCA provided in the first substrate 11A of the logic circuit LC includes a transistor having a gate structure in which a high-dielectric constant (for example, high-k) film including a material resistant to a high-temperature process and a metal gate electrode are stacked. In contrast, in a circuit LCB provided in the second substrate 30, a low-resistance region 30SL including a silicide such as CoSi₂ and NiSi is provided on a front surface of an impurity diffusion region in contact with a source electrode and a drain electrode. The silicide is formed with the use of the salicide (Self Aligned Silicide) process. The low-resistance region including the silicide includes a compound containing a material of the semiconductor substrate and a metal. This makes it possible to use a high-temperature process such as thermal oxidation, in forming the pixels P. Moreover, it is possible to reduce contact resistance, in the case where, in the circuit LCB provided in the second electrode 30 of the logic circuit LC, the low-resistance region 30SL including the silicide is provided on the front surface of the impurity diffusion region in contact with the source electrode and the drain electrode. As a result, it is possible to improve the calculation speed of the logic circuit LC.

### Modification Example 14

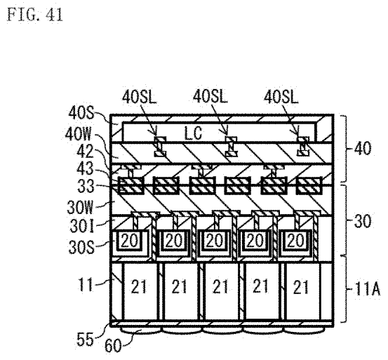

FIG. 41 illustrates a modification example of the cross-sectional configuration of the imaging element 10A according to the second embodiment and the modification examples thereof described above. In the logic circuit LC of the third substrate 40 according to the second embodiment and the modification examples thereof described above, a low-resistance region 40SL including a silicide such as CoSi₂ and NiSi may be provided on a front surface of an impurity diffusion region in contact with a source electrode and a drain electrode. The silicide is formed with the use of the salicide (Self Aligned Silicide) process. This makes it possible to use a high-temperature process such as thermal oxidation, in forming the pixels P. Moreover, it is possible to reduce contact resistance, in the case where, in the logic circuit LC, the low-resistance region 40SL including the silicide is provided on the front surface of the impurity diffusion region in contact with the source electrode and the drain electrode. As a result, it is possible to improve the calculation speed of the logic circuit LC.

### Application Example

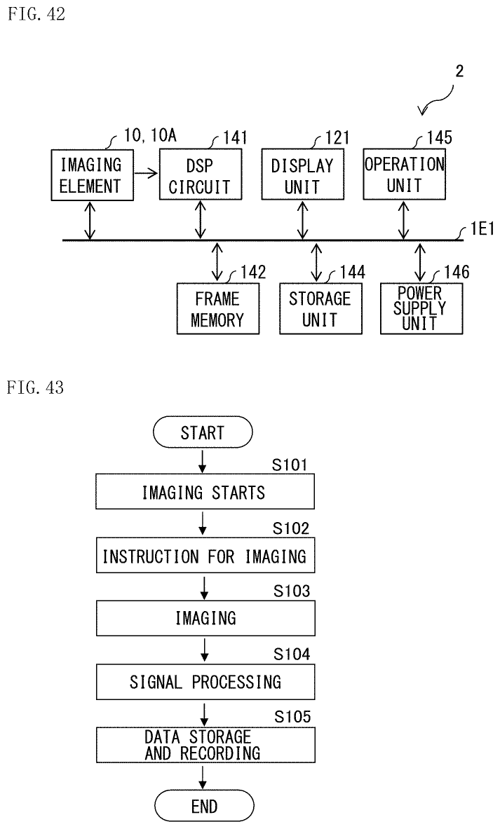

FIG. 42 illustrates an example of a schematic configuration of an imaging device 2 including the imaging element 10 or 10A according to the first and second embodiments and the modification examples thereof described above.

The imaging device 2 includes, for example, an electronic apparatus including an imaging device such as a digital still camera or a video camera, or a mobile terminal device such as a smartphone or a tablet terminal. The imaging device 2 includes, for example, the imaging element 10 or 10A according to the forgoing first and second embodiments and the modification examples thereof, a DSP circuit 141, a frame memory 142, a display unit 143, a storage unit 144, an operation unit 145, and a power supply unit 146. In the imaging device 2, the imaging element 10 or 10A according to the forgoing embodiments and the modification examples thereof, the DSP circuit 141, the frame memory 142, the display unit 143, the storage unit 144, the operation unit 145, and the power supply unit 146 are coupled to one another through a bus line 147.

The imaging element 10 or 10A according to the forgoing first and second embodiments and the modification examples thereof outputs image data corresponding to entering light. The DSP circuit 141 is a signal processing circuit that processes a signal (image data) outputted from the imaging element 10 or 10A according to the forgoing embodiments and the modification examples thereof. The frame memory 142 temporarily holds, in units of frames, the image data processed by the DSP circuit 141. The display unit 143 includes, for example, a panel display device such as a liquid crystal panel or an organic EL (Electro Luminescence) panel, and displays a moving image or a still image captured by the imaging element 10 or 10A according to the forgoing embodiments and the modification examples thereof. The storage unit 144 records the image data of the moving image or the still image captured by the imaging element 10 or 10A according to any of the forgoing first and second embodiments and the modification examples thereof, in a recording medium such as a semiconductor memory or a hard disk. The operation unit 145 outputs an operation instruction about various kinds of functions of the imaging device 2 in accordance with an operation by a user. The power supply unit 146 supplies various kinds of power serving as operation power for the imaging element 10 or 10A according to the forgoing first and second embodiments and the modification examples thereof, the DSP circuit 141, the frame memory 142, the display unit 143, the storage unit 144, and the operation unit 145, to these targets of supply as necessary.

Next, description is given of an imaging procedure in the imaging device 2.

FIG. 43 illustrates an example of a flowchart of an imaging operation in the imaging device 2. A user operates the operation unit 145 to give an instruction for a start of imaging (step S101). Thereupon, the operation unit 145 transmits an instruction for imaging to the imaging element 10 or 10A (step S102). Upon receiving the instruction for imaging, the imaging element 10 or 10A (specifically, the system control circuit 16) executes imaging of a predetermined imaging system (step S103).

The imaging element 10 or 10A outputs the image data captured by the imaging to the DSP circuit 141. Here, the image data is data of the pixel signals for all pixels generated on the basis of electric charges temporarily held in the FD section 26. The DSP circuit 141 performs predetermined signal processing (for example, noise reduction processing, etc.) on the basis of the image data supplied from the imaging element 10 or 10A (step S104). The DSP circuit 141 causes the frame memory 142 to hold the image data having been subjected to the predetermined signal processing, and the frame memory 142 stores the image data in the storage unit 144 (step S105). Thus, imaging is performed in the imaging device 2.

In the present application example, the imaging element 10 and 10A according to the embodiments and the modification examples thereof described above are applied to the imaging device 2. This leads to the downsizing or higher definition of the imaging element 10 and 10A. Hence, it is possible to provide the imaging device 2 of a small size or high definition.

### <Practical Application Examples to In-Vivo Information Acquisition System>

Furthermore, the technology according to the present disclosure (the present technology) is applicable to various products. For example, the technology according to the present disclosure may be applied to an endoscopic surgery system.

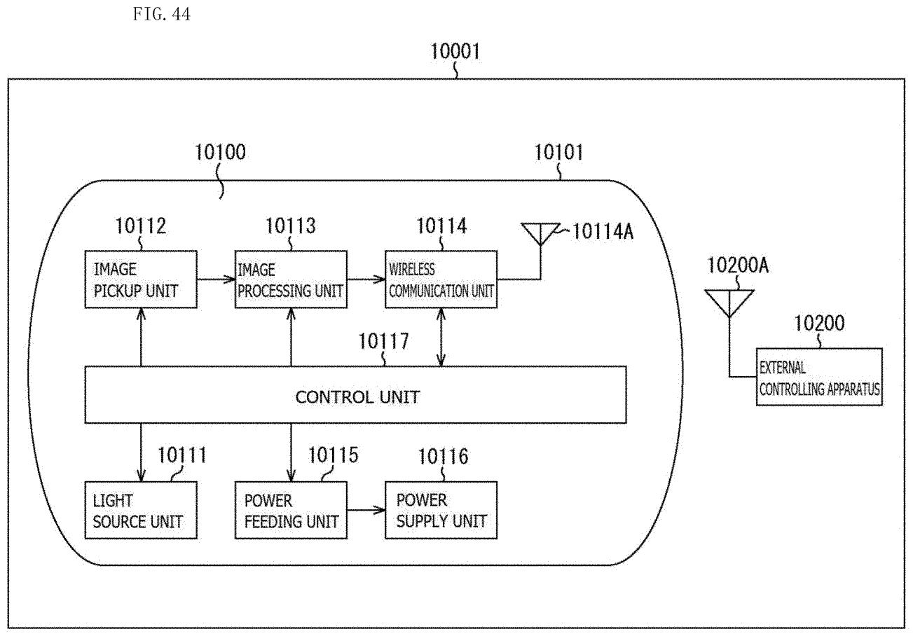

FIG. 44 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

The power supply unit 10116 includes a secondary battery and stores electric power generated by the power feeding unit 10115. In FIG. 44, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

In the forgoing, an example of the in-vivo information acquisition system is described to which the technology according to the present disclosure is applicable. The technology according to the present disclosure is applicable to, for example, the image pick up unit 10112 out of the configuration described above. This leads to enhancement in detection accuracy.

### <Practical Application Examples to Endoscopic Surgery System>

The technology according to the present disclosure (the present technology) is applicable to various products. For example, the technology according to the present disclosure may be applied to an endoscopic surgery system.

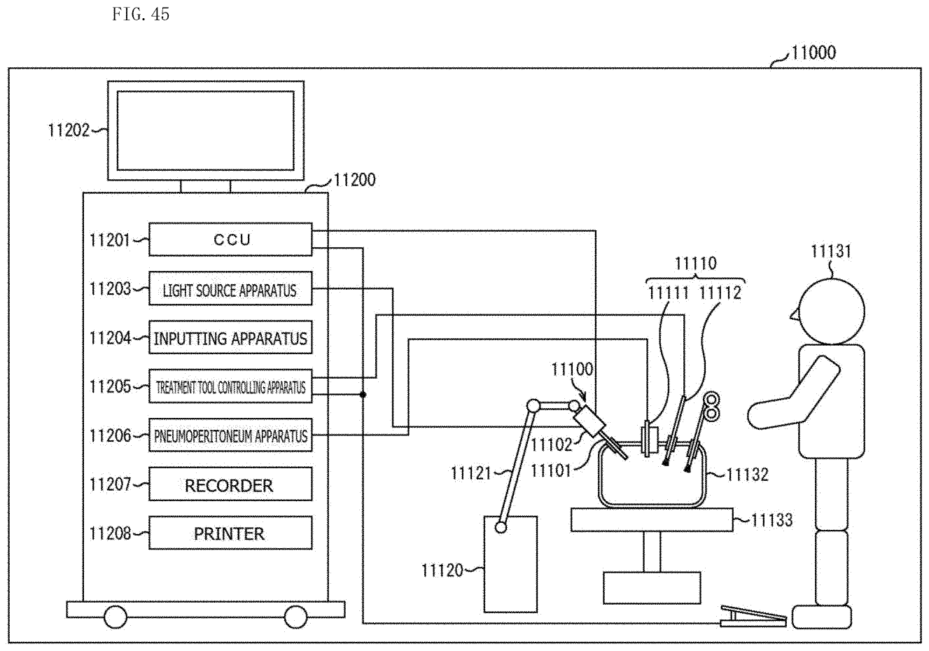

FIG. 45 is a view depicting an example of a schematic configuration of an endoscopic surgery system to which the technology according to an embodiment of the present disclosure (present technology) can be applied.

In FIG. 45, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

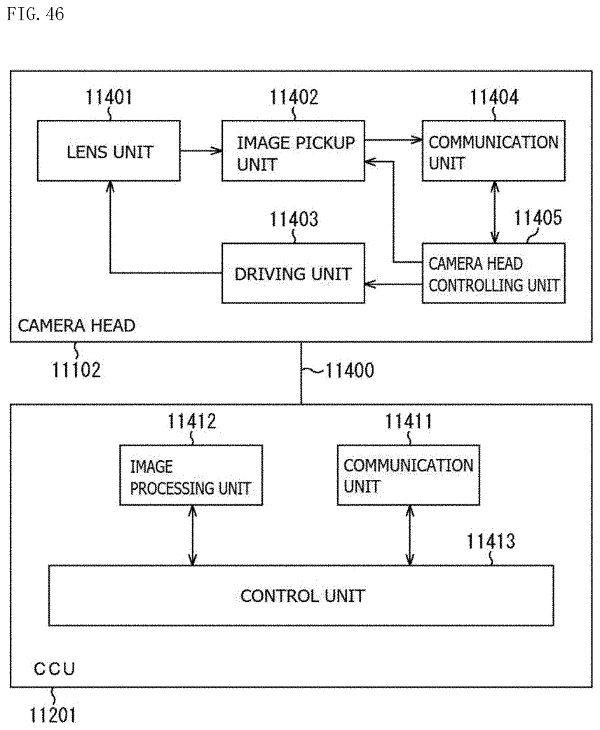

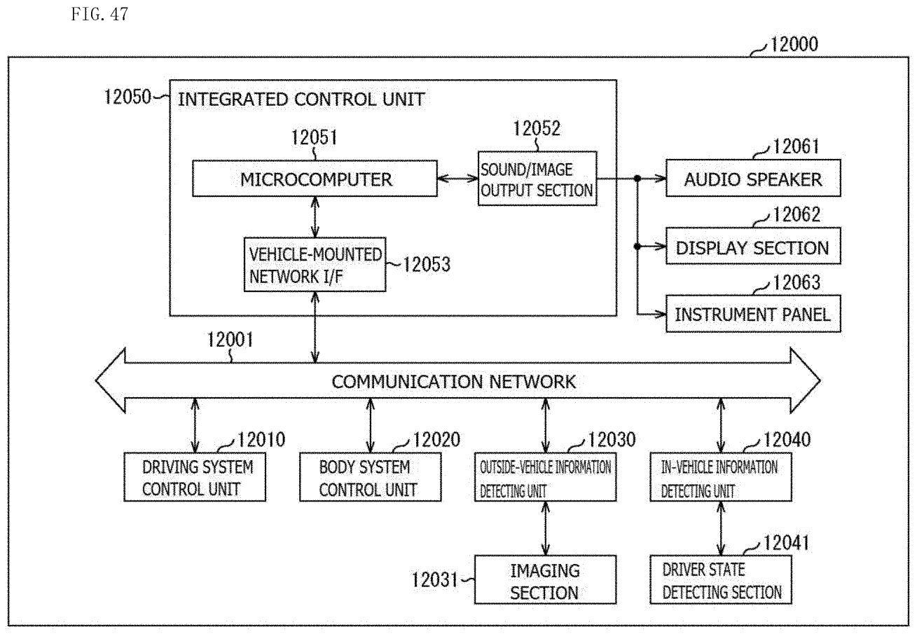

FIG. 46 is a block diagram depicting an example of a functional configuration of the camera head 11102 and the CCU 11201 depicted in FIG. 45.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the forgoing, an example of the endoscopic surgery system is described to which the technology according to the present disclosure is applicable. The technology according to the present disclosure is applicable to, for example, the image pick up unit 11402 out of the configuration described above. Applying the technology according to the present disclosure to the image pick up unit 11402 leads to enhancement in detection accuracy.

It is to be noted that the endoscopic surgery system is described here as an example, but the technology according to the present disclosure may be applied to other systems, for example, a micrographic surgery system, etc.

### <Practical Application Examples to Mobile Body>

The technology according to the present disclosure is applicable to various products. For example, the technology according to the present disclosure may be achieved as a device to be installed in any kind of a mobile body such as an automobile, an electric vehicle, a hybrid electric vehicle, a motorcycle, a bicycle, a personal mobility, an aircraft, a drone, a vessel, a robot, construction machinery, and agricultural machinery (tractor).

FIG. 47 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 47, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 47, an audio speaker 12061, a display section 12062, and an instrument panel 12063 are illustrated as the output device. The display section 12062 may, for example, include at least one of an on-board display and a head-up display.

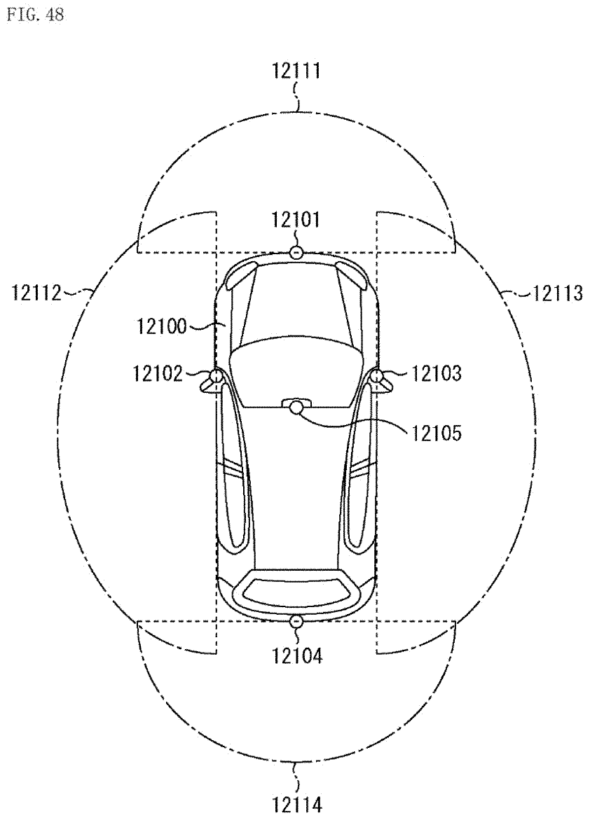

FIG. 48 is a diagram depicting an example of the installation position of the imaging section 12031.

In FIG. 48, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 48 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, an example of the vehicle control system is described to which the technology according to the present disclosure is applicable. The technology according to the present disclosure is applicable to the imaging unit 12031 out of the configuration described above. Applying the technology according to the present disclosure to the imaging unit 12031 makes it possible to obtain images that are easier to see. Hence, it is possible to alleviate a driver's fatigue.

Although contents of the present disclosure have been described above with reference to the embodiments and the modification examples, the contents of the present disclosure are not limited to the embodiments and the like described above, and may be modified in a variety of ways. For example, the layer configuration of the imaging element described in the forgoing embodiment is merely illustrative, and may further include other layers. Moreover, a material and a thickness of each layer are also illustrative, and not limited to those described above.

Moreover, in the forgoing embodiments and the like, the case is described in which the amplification transistor 24 is a junction-less transistor. However, it suffices that at least the reset transistor 23, the amplification transistor 24, or the selection transistor 25 is a junction-less transistor.

Furthermore, in the forgoing second embodiment, the case is described in which the amplification transistor 24 and the selection transistor 25 have a single gate structure. However, the amplification transistor 24 and the selection transistor 25 may have a double gate structure.

In addition, in the forgoing modification example 4, the case is described in which the channel region 23C of the reset transistor 23 is provided on the single fin (fin F1), and the channel regions 24C and 25C of the amplification transistor 24 and the selection transistor 25 are provided on the two fins (fins F2 and F3). However, the number of the fins is not limited thereto.

The effects described in the forgoing embodiments and the like are merely illustrative. The technology according to the present disclosure may produce other effects, or further include other effects.

It is to be noted that the present disclosure may have the following configurations. According to the solid-state imaging elements (1) and (2) and the imaging devices (1) and (2) having the following configurations, the output transistor includes the channel region of the same electrical conductivity type (first conductivity type) as the electrical conductivity type of the source-drain regions. This makes it possible to reduce the noise caused by the carrier trapped at the interface on the side of the channel region on which the gate electrode is disposed. Hence, it is possible to suppress the noise.

(1)

A solid-state imaging element including:

a first substrate including a photoelectric conversion section and a transfer transistor electrically coupled to the photoelectric conversion section;

a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and

a drive circuit that allows a signal electric charge generated in the photoelectric conversion section to be outputted through the transfer transistor and the output transistor.

(2)

The solid-state imaging element according to (1) above, in which

the gate electrode has a flat plate shape.

(3)

The solid-state imaging element according to (1) or (2) above, further including

a third substrate opposed to the first substrate with the second substrate in between and on which the drive circuit is provided.

(4)

A solid-state imaging element including:

a photoelectric conversion section;

a transfer transistor electrically coupled to the photoelectric conversion section;

an output transistor electrically coupled to the transfer transistor and including a channel region of a first electrical conductivity type, a gate electrode including a plurality of faces that covers the channel region, and source-drain regions of the first electrical conductivity type adjacent to the channel region; and

a drive circuit that allows a signal electric charge generated in the photoelectric conversion section to be outputted through the transfer transistor and the output transistor.

(5)

The solid-state imaging element according to (4) above, further including:

a first substrate including the photoelectric conversion section and the transfer transistor;

a second substrate provided to be opposed to the first substrate and including the output transistor; and

a third substrate opposed to the first substrate with the second substrate in between and on which the drive circuit is provided.

(6)

The solid-state imaging element according to any one of (1) to (5) above, further including

a gate insulating film between the gate electrode and the channel region.

(7)

The solid-state imaging element according to any one of (1) to (6) above, further including

an electric charge accumulation section to which the signal electric charge generated in the photoelectric conversion section is transferred from the transfer transistor.

(8)

The solid-state imaging element according to (7) above, further including:

an amplification transistor that outputs a signal in accordance with magnitude of a potential of the electric charge accumulation section;

a reset transistor that resets the potential of the electric charge accumulation section; and

a selection transistor that controls an output of the amplification transistor, in which

the output transistor includes at least the amplification transistor, the reset transistor, or the selection transistor.

(9)

The solid-state imaging element according to any one of (1) to (8) above, further including

a fin in which the channel region and the source-drain regions are provided.

(10)

The solid-state imaging element according to (9) above, in which

in the fin, a plurality of the channel regions and a plurality of the source-drain regions are provided continuously.

(11)

The solid-state imaging element according to (1) or (4) above, in which

the gate electrode includes a first face and a second face opposed with the channel region in between, and a third face that joins the first face and the second face.

(12)

The solid-state imaging element according to (11) above, in which

the gate electrode further includes a fourth face opposed to the third face with the channel region in between.

(13)

The solid-state imaging element according to any one of (1) to (12) above, in which

the gate electrode includes polysilicon of a second electrical conductivity type.

(14)

An imaging device including a solid-state imaging element, the solid-state imaging element including:

a first substrate including a photoelectric conversion section and a transfer transistor electrically coupled to the photoelectric conversion section;

a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and

a drive circuit that allows a signal electric charge generated in the photoelectric conversion section to be outputted through the transfer transistor and the output transistor.

(15)

An imaging device including a solid-state imaging element, the solid-state imaging element including:

a photoelectric conversion section;

a transfer transistor electrically coupled to the photoelectric conversion section;

an output transistor electrically coupled to the transfer transistor and including a channel region of a first electrical conductivity type, a gate electrode including a plurality of faces that covers the channel region, and source-drain regions of the first electrical conductivity type adjacent to the channel region; and

a drive circuit that allows a signal electric charge generated in the photoelectric conversion section to be outputted through the transfer transistor and the output transistor.

This application claims the benefit of Japanese Patent Application No. 2018-203704 filed with the Japan Patent Office on Oct. 30, 2018, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A solid-state imaging element comprising:
a first substrate including a photoelectric conversion section and a transfer transistor electrically coupled to the photoelectric conversion section;
a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and
a drive circuit that allows a signal electric charge generated in the photoelectric conversion section to be outputted through the transfer transistor and the output transistor.

2. The solid-state imaging element according to claim 1, wherein
the gate electrode has a flat plate shape.

3. The solid-state imaging element according to claim 1, further comprising
a third substrate opposed to the first substrate with the second substrate in between and on which the drive circuit is provided.

4. A solid-state imaging element comprising:
a photoelectric conversion section;
a transfer transistor electrically coupled to the photoelectric conversion section;
an output transistor electrically coupled to the transfer transistor and including a channel region of a first electrical conductivity type, a gate electrode including a plurality of faces that covers the channel region, and source-drain regions of the first electrical conductivity type adjacent to the channel region; and
a drive circuit that allows a signal electric charge generated in the photoelectric conversion section to be outputted through the transfer transistor and the output transistor.

5. The solid-state imaging element according to claim 4, further comprising:
a first substrate including the photoelectric conversion section and the transfer transistor;
a second substrate provided to be opposed to the first substrate and including the output transistor; and
a third substrate opposed to the first substrate with the second substrate in between and on which the drive circuit is provided.

6. The solid-state imaging element according to claim 1, further comprising
a gate insulating film between the gate electrode and the channel region.

7. The solid-state imaging element according to claim 1, further comprising
an electric charge accumulation section to which the signal electric charge generated in the photoelectric conversion section is transferred from the transfer transistor.

8. The solid-state imaging element according to claim 7, further comprising:
an amplification transistor that outputs a signal in accordance with magnitude of a potential of the electric charge accumulation section;
a reset transistor that resets the potential of the electric charge accumulation section; and
a selection transistor that controls an output of the amplification transistor, wherein
the output transistor comprises at least the amplification transistor, the reset transistor, or the selection transistor.

9. The solid-state imaging element according to claim 1, further comprising
a fin in which the channel region and the source-drain regions are provided.

10. The solid-state imaging element according to claim 9, wherein
in the fin, a plurality of the channel regions and a plurality of the source-drain regions are provided continuously.

11. The solid-state imaging element according to claim 1, wherein
the gate electrode includes a first face and a second face opposed with the channel region in between, and a third face that joins the first face and the second face.

12. The solid-state imaging element according to claim 11, wherein
the gate electrode further includes a fourth face opposed to the third face with the channel region in between.

13. The solid-state imaging element according to claim 1, wherein
the gate electrode includes polysilicon of a second electrical conductivity type.

14. An imaging device including a solid-state imaging element, the solid-state imaging element comprising:
a first substrate including a photoelectric conversion section and a transfer transistor electrically coupled to the photoelectric conversion section;
a second substrate provided to be opposed to the first substrate and including an output transistor, the output transistor including a gate electrode, a channel region of a first electrical conductivity type disposed to be opposed to the gate electrode, and source-drain regions of the first electrical conductivity type adjacent to the channel region; and
a drive circuit that allows a signal electric charge generated in the photoelectric conversion section to be outputted through the transfer transistor and the output transistor.

15. An imaging device including a solid-state imaging element, the solid-state imaging element comprising:
a photoelectric conversion section;
a transfer transistor electrically coupled to the photoelectric conversion section;
an output transistor electrically coupled to the transfer transistor and including a channel region of a first electrical conductivity type, a gate electrode including a plurality of faces that covers the channel region, and source-drain regions of the first electrical conductivity type adjacent to the channel region; and
a drive circuit that allows a signal electric charge generated in the photoelectric conversion section to be outputted through the transfer transistor and the output transistor.
